(19) United States
(12) Patent Application Publication
(10) Pub. No.: US 2024/0272661 A1
(43) Pub. Date: Aug. 15, 2024

(54) Voltage-to-Current Conversion

(71) Applicant: QUALCOMM Incorporated, San Diego, CA (US)

(72) Inventors: Asad Ali Nawaz, San Diego, CA (US); Ibrahim Ramez Chamas, Carlsbad, CA (US); Hayg-Taniel Dabag, San Diego, CA (US)

(21) Appl. No.: 18/449,364

(22) Filed: Aug. 14, 2023

Related U.S. Application Data
(60) Provisional application No. 63/484,918, filed on Feb. 14, 2023.

(51) Int. Cl. G05F 1/46; H03K 17/56

(52) U.S. Cl. CPC G05F 1/46; H03K 17/56

(57) ABSTRACT

An apparatus is disclosed for voltage-to-current conversion. In example aspects, the apparatus has a voltage-to-current converter including a plus input transistor, a minus input transistor, a plus current-source transistor, a minus current-source transistor, a plus resistor, and a minus resistor. The plus current-source transistor is coupled between the plus input transistor and a power distribution node. The minus current-source transistor is coupled between the minus input transistor and the power distribution node. The plus resistor is coupled between the plus input transistor and the plus current-source transistor. The minus resistor is coupled between the minus input transistor and the minus current-source transistor.

### CROSS-REFERENCE TO RELATED APPLICATION(S)

This application claims the benefit of U.S. Provisional Application No. 63/484,918, filed 14 Feb. 2023, the disclosure of which is hereby incorporated by reference in its entirety herein.

### TECHNICAL FIELD

This disclosure relates generally to signal communication or signal processing using an electronic device and, more specifically, to voltage-to-current conversion.

### BACKGROUND

Electronic devices include traditional computing devices such as desktop computers, notebook computers, smartphones, wearable devices like a smartwatch, internet servers, and so forth. Electronic devices also include other types of computing devices such as personal voice assistants (e.g., smart speakers), wireless access points or routers, thermostats and other automated controllers, robotics, automotive electronics, devices embedded in other machines like refrigerators and industrial tools, Internet of Things (IoT) devices, medical devices, and so forth. These various electronic devices provide services relating to productivity, communication, social interaction, security, health and safety, remote management, entertainment, transportation, and information dissemination. Thus, electronic devices play crucial roles in modern society.

Many of the services provided by electronic devices in today's interconnected world depend at least partly on electronic communications. Electronic communications can include, for example, those exchanged between two or more electronic devices using wireless or wired signals that are transmitted over one or more networks, such as the Internet, a Wi-Fi® network, or a cellular network. Electronic communications can therefore include wireless or wired transmissions and receptions. To transmit and receive communications, an electronic device can use a transceiver, such as a wireless transceiver that is designed for wireless communications.

Some electronic communications can thus be realized by propagating signals between two wireless transceivers at two different electronic devices. For example, using a wireless transmitter, a smartphone can transmit a wireless signal to a base station over the air as part of an uplink communication to support mobile services. Using a wireless receiver, the smartphone can receive a wireless signal that is transmitted from the base station via the air medium as part of a downlink communication to enable mobile services. In such cases, the base station can also have a wireless transceiver, including a wireless transmitter and a wireless receiver to participate in the wireless communications. With a smartphone, for instance, mobile services can include making voice and video calls, participating in social media interactions, sending messages, watching movies, sharing videos, performing searches, using map information or navigational instructions, finding friends, engaging in location-based services generally, transferring money, obtaining another service like a car ride, and so forth.

Many mobile and other communication-based services depend at least partly on the transmission or reception of wireless signals between two or more electronic devices. Consequently, researchers, electrical engineers, and other designers of electronic devices strive to develop wireless transceivers that can use wireless signals effectively to provide these and other mobile services.

### SUMMARY

In electrical or electronic signaling, information can be conveyed using voltage in a voltage mode or using current in a current mode. A voltage-to-current (V2I) converter or conversion procedure can convert from voltage-mode signaling to current-mode signaling. This voltage-to-current conversion component or procedure can inject nonlinearity or noise, including potentially both nonlinearity and noise, into a current-mode output signal. In example noise-related aspects, at least one degeneration resistor can be strategically positioned between an input transistor and a current-source transistor of a voltage-to-current converter. The input transistor can operate as a transconductance device that converts a voltage-mode input signal to the current-mode output signal. The degeneration resistance can redirect at least a portion of a noise-causing signal away from the input transistor. In a differential circuit, the noise-causing signal may be distributed between plus and minus input transistors using the degeneration resistor to cause at least a portion of the noise to be canceled from the current-mode output signal. In example linearity-related aspects, the current-source transistor of a voltage-to-current converter can be biased in a triode region instead of a saturation region. In the triode region, the current-source transistor can dynamically respond to changes in voltage by changing (e.g., increasing) current flow. The increased current flow can at least partially balance a current output that is being clipped at the input transistor to increase a linearity of the current-mode output signal. These and other implementations are described herein.

In an example aspect, an apparatus for voltage-to-current conversion is disclosed. The apparatus includes a voltage-to-current converter including a plus input transistor and a minus input transistor. The voltage-to-current converter also includes a plus current-source transistor coupled between the plus input transistor and a power distribution node and a minus current-source transistor coupled between the minus input transistor and the power distribution node. The voltage-to-current converter further includes a plus resistor coupled between the plus input transistor and the plus current-source transistor and a minus resistor coupled between the minus input transistor and the minus current-source transistor.

In an example aspect, an apparatus for voltage-to-current conversion is disclosed. The apparatus includes a voltage-to-current converter including a plus input transistor and a minus input transistor. The voltage-to-current converter also includes a plus current-source transistor coupled between the plus input transistor and a power distribution node and a minus current-source transistor coupled between the minus input transistor and the power distribution node. The voltage-to-current converter further includes means for reducing, in an output signal of the voltage-to-current converter, noise generated by the plus current-source transistor and means for reducing, in the output signal of the voltage-to-current converter, noise generated by the minus current-source transistor.

In an example aspect, a method for voltage-to-current conversion or operating a voltage-to-current converter is disclosed. The method includes receiving a voltage-mode input signal at an input transistor. The method also includes producing, using the input transistor, a current-mode output signal. The method additionally includes providing, using a current-source transistor, a current to the input transistor. The method further includes splitting noise generated by the current-source transistor between at least a first path including the input transistor and a resistor and a second path including another resistor.

In an example aspect, an apparatus is disclosed. The apparatus includes a voltage-to-current converter including a plus input transistor and a minus input transistor. The voltage-to-current converter also includes a plus current-source transistor coupled between the plus input transistor and a power distribution node, with the plus current-source transistor configured to be biased in a triode region of transistor operation during a voltage-to-current conversion procedure. The voltage-to-current converter additionally includes a minus current-source transistor coupled between the minus input transistor and the power distribution node, with the minus current-source transistor configured to be biased in the triode region of transistor operation during the voltage-to-current conversion procedure. The voltage-to-current converter further includes a conductive path coupled between the plus input transistor and the minus input transistor and between the plus current-source transistor and the minus current-source transistor.

### BRIEF DESCRIPTION OF DRAWINGS

FIG. 1 illustrates an environment with an example electronic device that has a wireless interface device, which includes an example voltage-to-current converter.

FIG. 2 is a schematic diagram illustrating an example radio-frequency (RF) front-end and an example transceiver that can each include at least one voltage-to-current converter.

FIG. 3 is a schematic diagram of an example transmit chain including a voltage-to-current converter.

FIG. 4-1 is a circuit diagram of an example voltage-to-current converter that illustrates example first aspects that can reduce noise in an output signal and example second aspects that can reduce nonlinearity in an output signal.

FIG. 4-2 is a circuit diagram of an example voltage-to-current converter that illustrates an example signal-noise-routing paradigm based on at least one position of at least one degeneration resistor of the depicted voltage-to-current converter.

FIG. 4-3 is a circuit diagram of another example voltage-to-current converter that illustrates another example signal-noise-routing paradigm based on at least one different position of at least one degeneration resistor of the depicted voltage-to-current converter to facilitate understanding the example first aspects that are described herein.

FIGS. 5-1 to 5-3 are circuit diagrams illustrating multiple example implementations of a voltage-to-current converter in accordance with at least the example first aspects.

FIGS. 6-1 to 6-4 are diagrams illustrating multiple example implementations of a voltage-to-current converter in accordance with at least the example second aspects.

FIGS. 7-1 and 7-2 are circuit diagrams illustrating multiple example implementations of a voltage-to-current converter in accordance with the example first aspects and the example second aspects for single-ended environments.

FIG. 8 is a flow diagram illustrating an example process for performing a voltage-to-current conversion procedure or operating a voltage-to-current converter.

### DETAILED DESCRIPTION

### Introduction and Overview

To facilitate transmission and reception of wireless signals, an electronic device can use a wireless interface device that includes a wireless transceiver and/or a radio-frequency (RF) front-end. Electronic devices communicate with wireless signals using electromagnetic (EM) signaling at various frequencies that exist on a portion of the EM spectrum. These wireless signals may travel between two electronic devices while oscillating at a particular frequency, such as a kilohertz (kHz) frequency, a megahertz (MHz) frequency, or a gigahertz (GHz) frequency. The EM spectrum is, however, a finite resource that limits how many signals can be simultaneously communicated in any given spatial area. There are already billions of electronic devices that use this limited resource. To enable a greater number of simultaneous communications using EM signaling, the finite EM spectrum is shared among electronic devices. The EM spectrum can be shared within a given spatial area using, for instance, frequency-division multiplexing (FDM) techniques and/or time-division multiplexing (TDM) techniques.

Techniques for FDM or TDM can entail separating the EM spectrum into different frequency bands and constraining communications to occur within an assigned frequency band at prescribed times. EM signals in different frequency bands can be communicated at the same time in a same area without significantly interfering with each other. Thus, a device can communicate using a wireless signal in a selected or assigned range of frequencies, which may be referred to as a target frequency band. To recover information carried by a signal that is received in a target frequency band, a receive chain of the wireless interface device can apply a mixer to the received signal to down-convert from the target frequency band to a lower frequency to facilitate further processing. To transmit a signal within a target frequency band, a transmit chain of a wireless interface device can apply a mixer to the signal to upconvert a relatively lower frequency to reach the target frequency band.

Accordingly, a mixer is employed to perform frequency up-conversion or frequency down-conversion. In some transmit chains, a voltage-to-current converter (V2I converter) is coupled between a digital-to-analog converter (DAC) and the mixer. The DAC may provide a voltage-mode signal to the voltage-to-current converter. The voltage-to-current converter converts the voltage mode-signal to a current-mode signal. With a voltage-mode signal, information in the signal is carried by a voltage level. In contrast, with a current-mode signal, information in the signal is carried by a current magnitude. The mixer operates on the current-mode signal from the voltage-to-current converter by increasing an oscillation frequency thereof. The transmit chain can further condition the upconverted current-mode signal that is output by the mixer before transmission.

In some environments, voltage-to-current converters can be a performance bottleneck with respect to operation of an active mixer in a transmit chain. The voltage-to-current converters can degrade transmit emissions by adding distortion or noise, including both distortion and noise in some circumstances. There are multiple approaches for building voltage-to-current converters. Each approach, however, “trades-off” between a variety of issues, such as linearity, noise, power consumption, and variability over process. Process variability reflects how a same circuit design may operate differently depending on random fluctuations in the fabrication process.

This document describes example implementations that provide simple, low-risk, and relatively compact voltage-to-current conversion circuits and techniques. Certain ones of these techniques leverage resistive degeneration to provide enhanced noise performance. Certain other ones of these techniques implement a bias scheme for a current-source transistor that can provide enhanced linearity. Moreover, these circuit components and techniques can be used together in a same voltage-to-current converter to thereby enhance noise and linearity performance-e.g., by decreasing noise and increasing linearity.

Some implementations are described in the context of a transmit chain, including for a base station of a cellular wireless system. A base-station chip, such as one for a 5^{th} Generation (5G) cellular system, is typically specified to meet a higher performance level than that for a user equipment (UE), including with regard to transmission linearity and noise. Nonetheless, described voltage-to-current converters can be implemented in the transmit chains of electronic devices besides base stations. Described voltage-to-current converters can also be implemented in receive chains of electronic devices. Further, this document describes voltage-to-current conversion techniques and apparatuses that can be implemented in circuits generally that utilize voltage-to-current conversion. For example, the described voltage-to-current conversion techniques and apparatuses can be used in a system-on-chip (SOC), an application processor, a modem processor, and so forth.

Generally, a voltage-to-current (V2I) conversion component or procedure can inject nonlinearity or noise, including potentially both nonlinearity and noise, into a current-mode output signal. In example noise-related aspects, at least one degeneration resistor can be strategically positioned between an input transistor and a current-source transistor of a voltage-to-current converter. The degeneration resistance can redirect at least a portion of a noise-causing signal away from the input transistor in a manner to reduce an impact from the noise on the output signal of the voltage-to-current converter. In a differential circuit, the noise-causing signal may be distributed between plus and minus input transistors using the degeneration resistor to cause at least a portion of the noise to be canceled from the current-mode output signal by better balancing the noise between the plus and minus components of the output signal.

In example linearity-related aspects, the current-source transistor of a voltage-to-current converter can be biased in a triode region instead of a saturation region. In the triode region, the current-source transistor can dynamically respond to changes in voltage by changing (e.g., increasing) current flow. The increased current flow can at least partially counteract a current output that is being clipped at the input transistor to increase a linearity of the current-mode output signal. This document also describes using the noise-related aspects in conjunction with the linearity-related aspects, and vice versa. These and other implementations are described herein.

### Description Examples

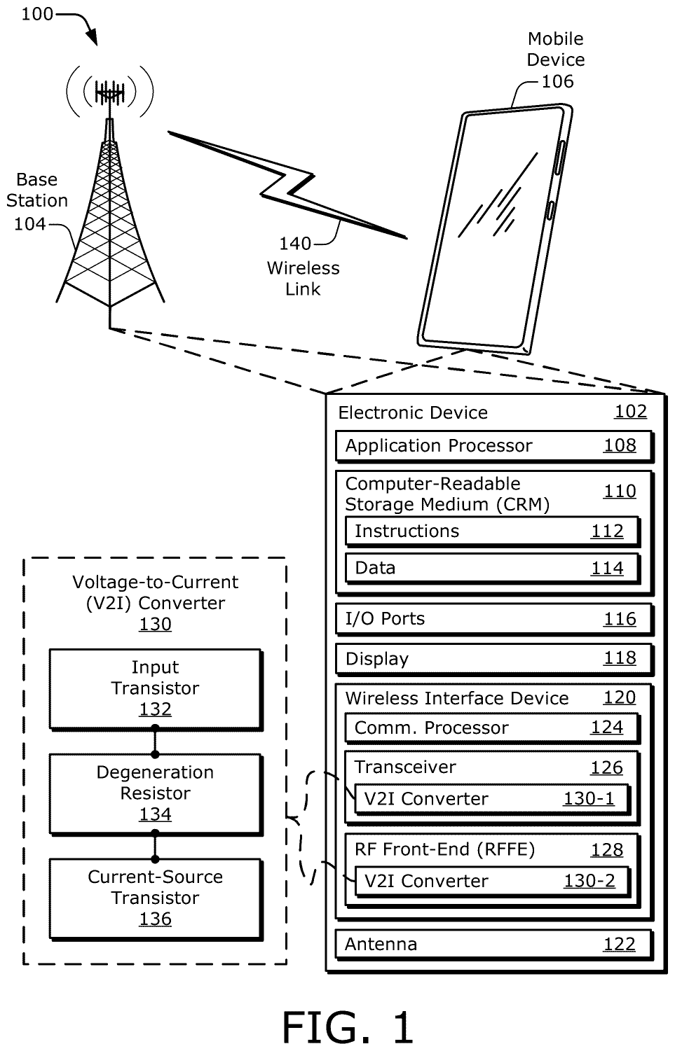

FIG. 1 illustrates an example environment 100 with an electronic device 102 that has a wireless interface device 120, which includes at least one example voltage-to-current converter 130 (V2I converter 130). This document describes example implementations of the voltage-to-current converter 130, which may be part of a radio-frequency front-end (RFFE), a transceiver, a communication processor, and so forth of an apparatus. Two examples of an electronic device 102 include a mobile device 106 and a base station 104. In the environment 100, the mobile device 106 communicates with the base station 104, and vice versa, through a wireless link 140.

In FIG. 1, the electronic device 102 is depicted as a smartphone or a base station tower. The electronic device 102, however, may be implemented as any suitable computing or other electronic device. Examples of an apparatus that can be realized as an electronic device 102 include a cellular base station, broadband router, access point, cellular or mobile phone, gaming device, navigation device, media device, laptop computer, desktop computer, tablet computer, and server computer. Other examples of an apparatus that can be realized as an electronic device 102 include a network-attached storage (NAS) device, smart appliance, vehicle-based communication system, Internet of Things (IoT) device, sensor or security device, asset tracker, fitness management device, wearable device such as intelligent glasses or smartwatch, wireless power device (transmitter or receiver), medical device, and so forth. An electronic device 102 may be referred to with different terminology, such as a base station (BS), a user equipment (UE), or a customer premises equipment (CPE).

Without loss of generality, the base station 104 communicates with the mobile device 106 via the wireless link 140, which may be implemented as any suitable type of wireless link that carries a communication signal. Although depicted as a base station tower of a cellular radio network, the base station 104 may represent or be implemented as another device, such as a satellite, terrestrial broadcast tower, access point, customer premises equipment (CPE), peer-to-peer device, mesh network node, fiber optic line interface, another electronic device as described above generally, and so forth. Hence, the wireless link 140 can extend between the mobile device 106 and the base station 104 in any of various manners.

The wireless link 140 can include a downlink of data or control information communicated from the base station 104 to the mobile device 106. The wireless link 140 can also include an uplink of other data or control information communicated from the mobile device 106 to the base station 104. The wireless link 140 may be implemented using any suitable wireless communication protocol or standard. Examples of such protocols and standards include a 3^{rd} Generation Partnership Project (3GPP) Long-Term Evolution (LTE) standard, such as a 4^{th} Generation (4G), a 5^{th} Generation (5G), or a 6^{th} Generation (6G) cellular standard; an IEEE 802.11 standard, such as 802.11g, ac, ax, ad, aj, or ay standard (e.g., Wi-Fi® 6 or WiGig®); an IEEE 802.16 standard (e.g., WiMAX®); a Bluetooth® standard; an ultra-wideband (UWB) standard (e.g., IEEE 802.15.4); and so forth. In some implementations, the wireless link 140 may provide power wirelessly, and the mobile device 106 or the base station 104 may comprise a power source or a power sink.

As shown for some implementations, the electronic device 102 can include at least one application processor 108 and at least one computer-readable storage medium 110 (CRM 110). The application processor 108 may include any type of processor, such as a central processing unit (CPU) or a multi-core processor, that is configured to execute processor-executable instructions (e.g., code) stored by the CRM 110. The CRM 110 may include any suitable type of data storage media, such as volatile memory (e.g., random-access memory (RAM)), non-volatile memory (e.g., Flash memory), optical media (e.g., a disc), magnetic media (e.g., a disk or tape), and so forth. In the context of this disclosure, the CRM 110 is implemented to store instructions 112, data 114, and other information of the electronic device 102, and thus the CRM 110 does not include transitory propagating signals or carrier waves.

The electronic device 102 may also include one or more input/output ports 116 (I/O ports 116) and at least one display 118. The I/O ports 116 enable data exchanges or interaction with other devices, networks, or users. The I/O ports 116 may include serial ports (e.g., universal serial bus (USB®) ports), Ethernet ports, parallel ports, audio ports, infrared (IR) ports, camera or other sensor ports, and so forth. The display 118 can be realized as a display screen or a projection that presents graphical images provided by other components of the electronic device 102, such as a user interface (UI) associated with an operating system, program, or application. Alternatively or additionally, the display 118 may be implemented as a display port or virtual interface through which graphical content of the electronic device 102 is communicated or presented.

The electronic device 102 further includes at least one wireless interface device 120 and at least one antenna 122. The example wireless interface device 120 provides connectivity to respective networks and peer devices via a wireless link, which may be configured similarly to or differently from the wireless link 140. The wireless interface device 120 may facilitate communication over any suitable type of wireless network, such as a wireless local area network (LAN) (WLAN), wireless personal-area-network (PAN) (WPAN), peer-to-peer (P2P) network, mesh network, cellular network, wireless wide-area-network (WAN) (WWAN), and/or navigational network (e.g., the Global Positioning System (GPS) of North America or another Satellite Positioning System (SPS) or Global Navigation Satellite System (GNSS)). In the context of the example environment 100, the electronic device 102 can communicate various data and control information bidirectionally with another device (e.g., engage in communications between the base station 104 and the mobile device 106) via the wireless interface device 120. The electronic device 102 may, however, communicate directly with other peer devices, an alternative wireless network, and the like. Also, as described above, an electronic device 102 may alternatively be implemented as another apparatus as set forth herein.

As shown in FIG. 1, the wireless interface device 120 can include at least one communication processor 124, at least one transceiver 126, and at least one radio-frequency front-end 128 (RFFE 128). These components process data information, control information, and signals associated with communicating information for the electronic device 102 via the antenna 122. The communication processor 124 may be implemented as at least part of a system-on-chip (SoC), as a modem processor, or as a baseband radio processor (BBP) that enables a digital communication interface for data, voice, messaging, or other applications of the electronic device 102. The communication processor 124 can include a digital signal processor (DSP) or one or more signal-processing blocks (not shown) for encoding and modulating data for transmission and for demodulating and decoding received data. Additionally, the communication processor 124 may also manage (e.g., control or configure) aspects or operation of the transceiver 126, the RF front-end 128, and other components of the wireless interface device 120 to implement various communication protocols or communication techniques.

In some cases, the application processor 108 and the communication processor 124 can be combined into one module or integrated circuit (IC), such as an SoC. Regardless, the application processor 108, the communication processor 124, or a processor generally can be operatively coupled to one or more other components, such as the CRM 110 or the display 118, to enable control of, or other interaction with, the various components of the electronic device 102. For example, at least one processor 108 or 124 can present one or more graphical images on a display screen implementation of the display 118 based on one or more wireless signals communicated (e.g., transmitted or received) via the at least one antenna 122 using components of the wireless interface device 120. Further, the application processor 108 or the communication processor 124, including a combination thereof, can be realized using digital circuitry that implements logic or functionality that is described herein. Additionally, the communication processor 124 may also include or be associated with a memory (not separately depicted) to store data and processor-executable instructions (e.g., code), such as the same CRM 110 or another CRM.

As shown, the wireless interface device 120 can include at least one voltage-to-current converter 130, which is described below. More specifically, the transceiver 126 can include at least one voltage-to-current converter 130-1, or the RF front-end 128 can include at least one voltage-to-current converter 130-2 (including both components can have at least one voltage-to-current converter 130 in accordance with an optional, but permitted herein, “inclusive-or” interpretation of the word “or”). The transceiver 126 can also include circuitry and logic for filtering, switching, amplification, channelization, frequency translation, and so forth.

Frequency translation functionality may include an up-conversion or a down-conversion of frequency that is performed through a single conversion operation (e.g., with a direct-conversion architecture) or through multiple conversion operations (e.g., with a superheterodyne architecture). The transceiver 126 can perform such frequency conversion (e.g., frequency translation) by using a mixer circuit (not shown in FIG. 1). Generally, the transceiver 126 can include filters, switches, amplifiers, mixers, and so forth for routing and conditioning signals that are transmitted or received via the antenna 122.

In addition to the voltage-to-current converter 130-1, the transceiver 126 can include an analog-to-digital converter (ADC) or a digital-to-analog converter (DAC) (not shown in FIG. 1). In operation, an ADC can convert analog signals to digital signals, and a DAC can convert digital signals to analog signals. Generally, an ADC or a DAC can be implemented as part of the communication processor 124, as part of the transceiver 126, or separately from both (e.g., as another part of an SoC or as part of the application processor 108).

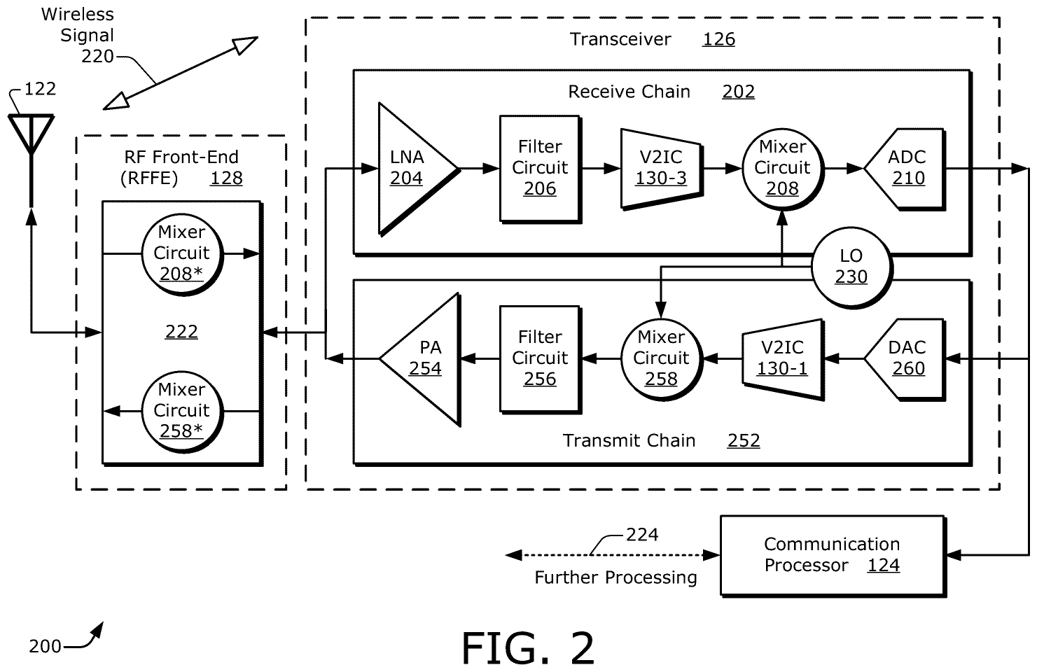

The components or circuitry of the transceiver 126 can be implemented in any suitable fashion, such as with combined transceiver logic or separately as respective transmitter and receiver entities. In some cases, the transceiver 126, or the RF front-end 128, is implemented with multiple or different sections to implement respective transmitting and receiving operations (e.g., with separate transmit and receive chains as depicted in FIG. 2). Although not shown in FIG. 1, the transceiver 126 may include logic to perform in-phase/quadrature (I/Q) operations, such as synthesis, phase correction, modulation, demodulation, and the like.

The RF front-end 128 can also include one or more voltage-to-current converters—such as the voltage-to-current converter 130-2—one or more filters, one or more switches, or one or more amplifiers for conditioning signals received via the antenna 122 or for conditioning signals to be transmitted via the antenna 122. The RF front-end 128 may also include a local oscillator, phase shifter (PS), peak detector, power meter, gain control block, antenna tuning circuit, N-plexer, balun, and the like. Configurable components of the RF front-end 128, such as some phase shifters, an automatic gain controller (AGC), or a reconfigurable version of the voltage-to-current converter 130-2, may be controlled by the communication processor 124 to implement communications in various modes, with different frequency bands, using beamforming, to reduce noise or nonlinearity, or to trade-off between noise and nonlinearity. The communication processor 124 can similarly control operation of one or more components of the transceiver 126, such as the voltage-to-current converter 130-1.

In some implementations, the antenna 122 is implemented as at least one antenna array that includes multiple antenna elements. Thus, as used herein, an “antenna” can refer to at least one discrete or independent antenna, to at least one antenna array that includes multiple antenna elements, or to a portion of an antenna array (e.g., an antenna element), depending on context or implementation.

In example implementations, the wireless interface device 120 includes at least one voltage-to-current converter 130. The voltage-to-current converter 130 may be positioned at the communication processor 124, the transceiver 126, the RF front-end 128, or a combination thereof, including by being distributed across two or more sections or parts of the wireless interface device 120. In FIG. 1, an example voltage-to-current converter 130 is depicted as being part of a transceiver 126 as a voltage-to-current converter 130-1, as being part of an RF front-end 128 as a voltage-to-current converter 130-2, and so forth. Described implementations of a voltage-to-current converter 130 can, however, additionally or alternatively be employed in other portions of the wireless interface device 120 or in other portions of the electronic device 102 generally.

As set forth above, a voltage-to-current converter 130 can be included in an electronic device besides a cell phone, such as a base station 104 or wireless access point. Also, with a base station (or with another electronic device that uses a superheterodyne architecture), a mixer for an, e.g., intermediate frequency (IF) section of a wireless interface device 120 may be coupled to a voltage-to-current converter 130 as described herein. However, a voltage-to-current converter 130 can be deployed separately from a mixer, in another section of a wireless interface device 120 (e.g., in an RF section or a baseband section), and so forth. Other electronic device apparatuses that can employ a voltage-to-current converter 130 include a laptop, communication hardware of a vehicle, a wireless access point, a wearable device, and so forth as described herein.

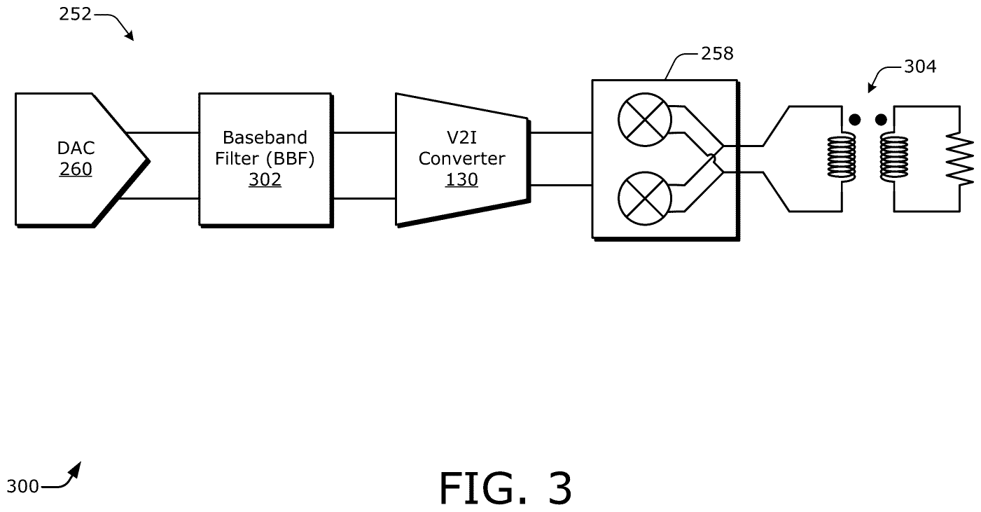

In example implementations, the voltage-to-current converter 130 can include at least one input transistor 132, at least one degeneration resistor 134, and at least one current-source transistor 136. In some cases, the voltage-to-current converter 130 may be coupled to an input of a mixer, as described below with reference to FIGS. 2 and 3. Although certain components are shown as being part of an example voltage-to-current converter 130 in FIG. 1, a given voltage-to-current converter may have more, fewer, or different components. Examples of voltage-to-current converters, including the operation thereof, are described below with reference to FIGS. 4-1 through 8. As used herein, unless context dictates otherwise, a voltage-to-current converter can be realized as a circuit—e.g., as a voltage-to-current conversion circuit.

As described herein for example first aspects, the at least one degeneration resistor 134 can be positioned so as to distribute a noise-carrying signal in manner(s) that reduce how much of the noise reaches or adversely impacts an output signal of the voltage-to-current converter 130. As described herein for example second aspects, during operation of the voltage-to-current converter 130, the current-source transistor 136 can be biased in a triode region so as to compensate for compression in the input transistor 132 in manner(s) that increase a linearity of the output signal of the voltage-to-current converter 130. These techniques may also be used together to improve noise and linearity. Thus, described implementations can reduce noise in some cases, nonlinearity in other cases, and both nonlinearity and noise in certain other cases. Example approaches to improving voltage-to-current conversion procedures and apparatuses are described below with reference to FIGS. 4-1 through 8. Next, however, this document describes with reference to FIG. 2 example implementations of a transceiver and an RF front-end that can include at least one voltage-to-current converter 130.

FIG. 2 is a schematic diagram of circuitry 200 illustrating an example RF front-end 128 and an example transceiver 126 that can each include at least one mixer circuit, which may be preceded by a respective voltage-to-current converter 130. FIG. 2 also depicts an antenna 122 and a communication processor 124. The communication processor 124 communicates one or more data signals to other components, such as the application processor 108 of FIG. 1, for further processing at 224 (e.g., for processing at an application level) for reception operations. For transmission operations, the communication processor 124 communicates one or more data signals from other components to the transceiver 126.

As shown, the circuitry 200 can include a mixer circuit 208, a mixer circuit 258, a mixer circuit 208*, or a mixer circuit 258*, including one to four of such mixer circuits. Although a voltage-to-current converter 130-1 and 130-3 is shown preceding only the mixer circuits 258 and 208, respectively, any of the mixer circuits may be preceded by a voltage-to-current converter 130. Further, the circuitry 200 may include a different quantity of mixers or voltage-to-current converters (e.g., more or fewer), may include mixers or voltage-to-current converters that are coupled together differently, may include mixers or voltage-to-current converters at different locations, and so forth.

As illustrated from left to right, in example implementations, the antenna 122 is coupled to the RF front-end 128, and the RF front-end 128 is coupled to the transceiver 126. The transceiver 126 is coupled to the communication processor 124. The example RF front-end 128 includes at least one signal propagation path 222. The at least one signal propagation path 222 can include at least one mixer circuit, such as the mixer circuit 208* for frequency down-conversion operations for receptions and the mixer circuit 258* for frequency up-conversion operations for transmissions. The example transceiver 126 includes at least one receive chain 202 (or receive path 202) and at least one transmit chain 252 (or transmit path 252). Although only one RF front-end 128, one transceiver 126, and one communication processor 124 are shown at the circuitry 200, an electronic device 102, or a wireless interface device 120 thereof, can include multiple instances of any or all such components. Also, although only certain components are explicitly depicted in FIG. 2 and are shown coupled together in a particular manner, the transceiver 126 or the RF front-end 128 may include other non-illustrated components (e.g., switches or diplexers), more or fewer components, differently coupled arrangements of components, and so forth.

In some implementations, the RF front-end 128 couples the antenna 122 to the transceiver 126 via the signal propagation path 222. In operation, the signal propagation path 222 carries a signal between the antenna 122 and the transceiver 126. During or as part of the signal propagation, the signal propagation path 222 conditions the propagating signal, such as with the mixer circuit 208* or the mixer circuit 258*. This enables the RF front-end 128 to couple a wireless signal 220 from the antenna 122 to the transceiver 126 as part of a reception operation. The RF front-end 128 also enables a transmission signal to be coupled from the transceiver 126 to the antenna 122 as part of a transmission operation to emanate a wireless signal 220. Although not explicitly shown in FIG. 2, an RF front-end 128, or a signal propagation path 222 thereof, may include one or more other components, such as another mixer, a filter, an amplifier (e.g., a power amplifier (PA) or a low-noise amplifier (LNA)), an N-plexer, a phase shifter, a transformer, a diplexer, at least one voltage-to-current converter 130, one or more switches, and so forth.

In some implementations, the transceiver 126 can include at least one receive chain 202, at least one transmit chain 252, or at least one receive chain 202 and at least one transmit chain 252. From left to right, the receive chain 202 can include a low noise amplifier 204 (LNA 204), a filter circuit 206, a voltage-to-current converter 130-3 (V2IC 130-3), the mixer circuit 208 for frequency down-conversion, and an ADC 210. The transmit chain 252 can include a power amplifier 254 (PA 254), a filter circuit 256, the mixer circuit 258 for frequency up-conversion, the voltage-to-current converter 130-1 (V2IC 130-1), and a DAC 260. However, the receive chain 202 or the transmit chain 252 can include other components-for example, additional mixers or voltage-to-current converters, multiple filters, at least one transformer, one or more buffers, or at least one phase-locked loop-that are electrically or electromagnetically coupled anywhere along the depicted receive and transmit chains.

The receive chain 202 is coupled between the signal propagation path 222 of the RF front-end 128 and the communication processor 124—e.g., via the low-noise amplifier 204 and the ADC 210, respectively. The transmit chain 252 is coupled between the signal propagation path 222 and the communication processor 124—e.g., via the power amplifier 254 and the DAC 260, respectively. The transceiver 126 can also include at least one local oscillator 230 (LO 230) that is coupled to the mixer circuit 208 or the mixer circuit 258, including to both mixer circuits. For example, the transceiver 126 can include one local oscillator 230 for each transmit/receive chain pair, one local oscillator 230 per transmit chain and one local oscillator 230 per receive chain, multiple local oscillators 230 per transmit or receive chain, and so forth. Each of the mixer circuit 208* and the mixer circuit 258* of the RF front-end 128 may also be coupled to the same local oscillator 230 or to a different local oscillator (not shown in FIG. 2).

As depicted along a signal propagation direction for certain example implementations of the receive chain 202, the antenna 122 is coupled to the low noise amplifier 204 via the signal propagation path 222 and the mixer circuit 208* thereof, and the low noise amplifier 204 is coupled to the filter circuit 206. The filter circuit 206 is coupled to the voltage-to-current converter 130-3. The voltage-to-current converter 130-3 is coupled to the mixer circuit 208, and the mixer circuit 208 is coupled to the ADC 210. The ADC 210 is in turn coupled to the communication processor 124. As depicted along a signal propagation direction for certain example implementations of the transmit chain 252, the communication processor 124 is coupled to the DAC 260, and the DAC 260 is coupled to the mixer circuit 258 via the voltage-to-current converter 130-1. As shown, the voltage-to-current converter 130-1 is coupled between the DAC 260 and the mixer circuit 258. Thus, the DAC 260 is coupled to the voltage-to-current converter 130-1, and the voltage-to-current converter 130-1 is coupled to the mixer circuit 258. The mixer circuit 258 is coupled to the filter circuit 256, and the filter circuit 256 is coupled to the power amplifier 254. The power amplifier 254 is coupled to the antenna 122 via the signal propagation path 222 using the mixer circuit 258* thereof. Although only one receive chain 202 and one transmit chain 252 are explicitly shown, an electronic device 102, or a transceiver 126 thereof, can include multiple instances of either or both components. Although the ADC 210 and the DAC 260 are illustrated as being separately coupled to the communication processor 124, they may share a bus or other means for communicating with the processor 124.

As part of an example signal-receiving operation, the mixer circuit 208* (if present) of the signal propagation path 222 down-converts a received signal (e.g., to an intermediate frequency (IF)) and forwards the down-converted signal to the low-noise amplifier 204. The low-noise amplifier 204 accepts the down-converted signal from the RF front-end 128 and provides an amplified signal to the filter circuit 206 based on the accepted signal. The filter circuit 206 filters the amplified signal and provides a filtered signal to the voltage-to-current converter 130-3. The voltage-to-current converter 130-3 converts a filtered voltage-based signal to a current-based signal and provides the current-based signal to the mixer circuit 208.

The mixer circuit 208 performs a frequency down-conversion operation on the filtered current-mode signal to down-convert from one frequency to a lower frequency (e.g., from the IF to a baseband frequency (BBF) if the mixer circuit 208* is present or from a radio frequency (RF) to an IF or BBF in the absence of the mixer circuit 208*). The mixer circuit 208, or multiple mixer circuits, can perform the frequency down-conversion in a single conversion step or through multiple conversion steps using at least one local oscillator 230. The mixer circuit 208 can provide a down-converted analog signal to the ADC 210 for analog-to-digital conversion and subsequent forwarding to the communication processor 124 as a digital signal by the ADC 210.

As part of an example signal-transmitting operation, the DAC 260 converts a digital signal received from the communication processor 124 to an analog signal. The DAC 260 forwards the analog signal to the voltage-to-current converter 130-1, and the voltage-to-current converter 130-1 accepts the analog signal from the DAC 260. In some cases, the analog signal is in a voltage-mode. The voltage-to-current converter 130-1 converts the voltage-mode analog signal to a current-mode analog signal. The voltage-to-current converter 130-1 provides the current-mode analog signal to the mixer circuit 258.

The mixer circuit 258 accepts the analog signal at a BBF or an IF from the voltage-to-current converter 130-1. The mixer circuit 258 upconverts the analog signal to a higher frequency, such as to an IF or an RF, to produce a higher-frequency signal using a signal generated by the local oscillator 230 to have a target synthesized frequency. The mixer circuit 258 provides the RF or other upconverted signal to the filter circuit 256. The filter circuit 256 filters the upconverted IF or RF signal and provides a filtered signal to the power amplifier 254. Thus, after the filtering by the filter circuit 256, the power amplifier 254 amplifies the filtered signal and provides an amplified signal to the signal propagation path 222 for signal conditioning. The RF front-end 128 can, for instance if the amplified signal is at IF, use the mixer circuit 258* of the signal propagation path 222 to provide an RF signal to the antenna 122 for emanation as a wireless signal 220.

Example implementations of a voltage-to-current converter 130, as described herein, may be deployed to precede (from a signal propagation perspective) one or more of the example mixer circuits 208, 258, 208*, or 258* in the transceiver 126 or the RF front-end 128 or at other mixer circuits of an electronic device 102 (not shown in FIG. 2). Nonetheless, one or more voltage-to-current converters can be deployed: in alternative locations along a transmit chain 252 or a receive chain 202, as part of an RF front-end 128, with or without being coupled to an input or an output of a mixer circuit or DAC, in a discrete or integrated form, in other portions of an electronic device, and so forth.

The circuitry 200 depicts just a few examples for a transceiver 126 and an RF front-end 128. In some cases, the various components that are illustrated in the drawings using separate schematic blocks or circuit elements may be manufactured or packaged in different discrete manners. For example, one physical module may include components of the RF front-end 128 and some components of the transceiver 126, and another physical module may combine the communication processor 124 with the “remaining” components of the transceiver 126.

Further, in some cases, the antenna 122 may be co-packaged into a module with at least some components of the RF front-end 128 or the transceiver 126. For instance, in a non-limiting example corresponding to a mmW implementation, the transceiver 126 may provide an IF signal to the RF front-end 128. In some of such cases, the RF front-end 128 may be co-packaged into a module with an antenna array version of the antenna 122. Here, the RF front-end 128 includes one or more mixer circuits that are configured to upconvert and down-convert between the IF/RF signals. The RF front-end 128 can also provide further signal conditioning, such as phase shifting and the like for beamforming. In another non-limiting example, such as for a 5G New Radio (NR) Frequency Range 1 (FR1) implementation, the RF front-end 128 may not include a mixer (e.g., with a direct-conversion architecture in which frequency translation between BB and RF occurs in the transceiver 126). Even without a mixer, the RF front-end 128 may nonetheless include other components, such as a power amplifier, a low-noise amplifier, a filter, a voltage-to-current converter 130, or other conditioning circuitry for processing after or before (for transmission or reception operations, respectively) the signal is processed by the transceiver 126.

In alternative implementations, one or more components may be physically or logically “shifted” to a different part of the wireless interface device 120 as compared to the illustrated circuitry 200 and/or may be incorporated into a different module. For example, a low-noise amplifier 204 or a power amplifier 254 may alternatively or additionally be deployed in the RF front-end 128. Similarly, an ADC 210 or a DAC 260 may alternatively be deployed in the communication processor 124. Further, a receive chain or a transmit chain may be present in the RF front-end 128, and/or the depicted receive chain 202 or transmit chain 252 may be extended into the RF front-end 128 such that the chain(s) are at least partially distributed across the transceiver 126 and the RF front-end 128.

FIG. 3 is a schematic diagram 300 illustrating an example transmit chain 252 including a voltage-to-current converter 130. As illustrated, the transmit chain 252 includes a DAC 260, a baseband filter 302 (BBF 302), a voltage-to-current converter 130) (V2I converter 130), a mixer circuit 258, and a transformer 304. The baseband filter 302 is coupled between the DAC 260 and the voltage-to-current converter 130. The voltage-to-current converter 130 is coupled between the baseband filter 302 and the mixer circuit 258. The mixer circuit 258 is coupled between the voltage-to-current converter 130 and the transformer 304.

In some cases, the mixer circuit 258 is implemented as an active mixer that feeds into the transformer 304 for further transmission-signal processing prior to signal emanation. In the schematic diagram 300, the components are coupled together with dual lines to represent a differential (or balanced) signaling environment. In such cases, the transmit chain 252 can deploy two example voltage-to-current converters: one for differential in-phase (I) signals and another for quadrature (Q) signals. Here, a differential voltage-to-current converter 130 may process two signal components. If 45° I and Q signals are also employed, then the transmit chain 252 can deploy four voltage-to-current converters to process the eight resulting signal components.

Although the transmit chain 252 in FIG. 3 depicts dual signaling lines for differential signaling, the principles described herein can be employed in single-ended (or unbalanced) signaling environments. Example single-ended circuits are described below with reference to FIGS. 7-1 and 7-2. Further, certain illustrations that depict dual signal lines may be applicable to single-ended implementations, like the schematic diagram 300. Conversely, certain illustrations that depict single signal lines may be applicable to differential implementations, like the schematic diagram 200 of FIG. 2.

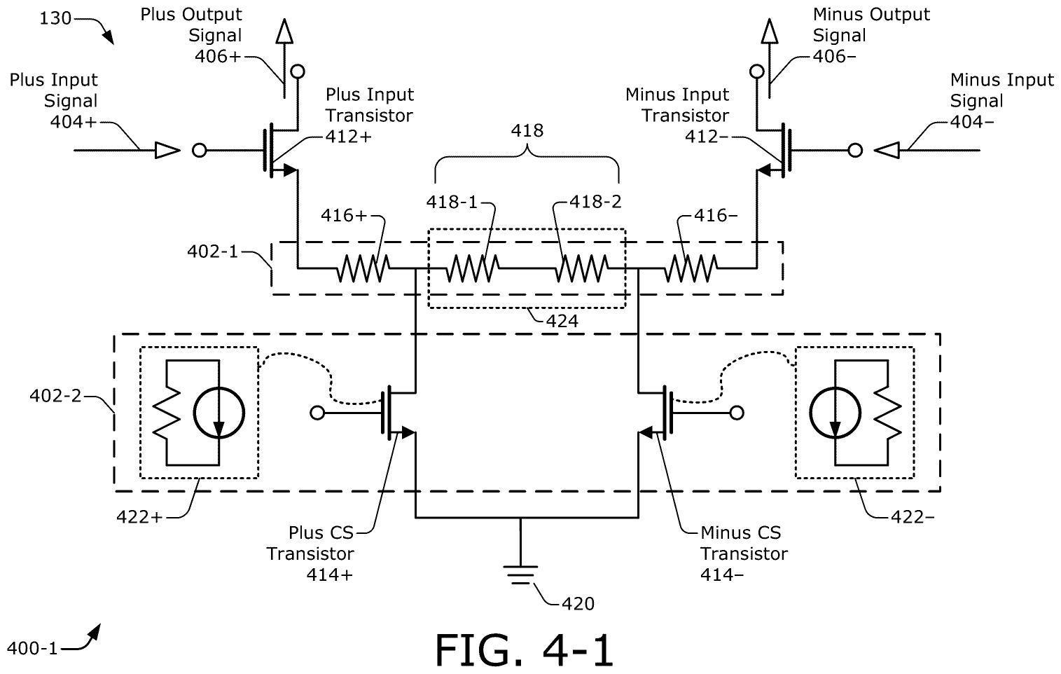

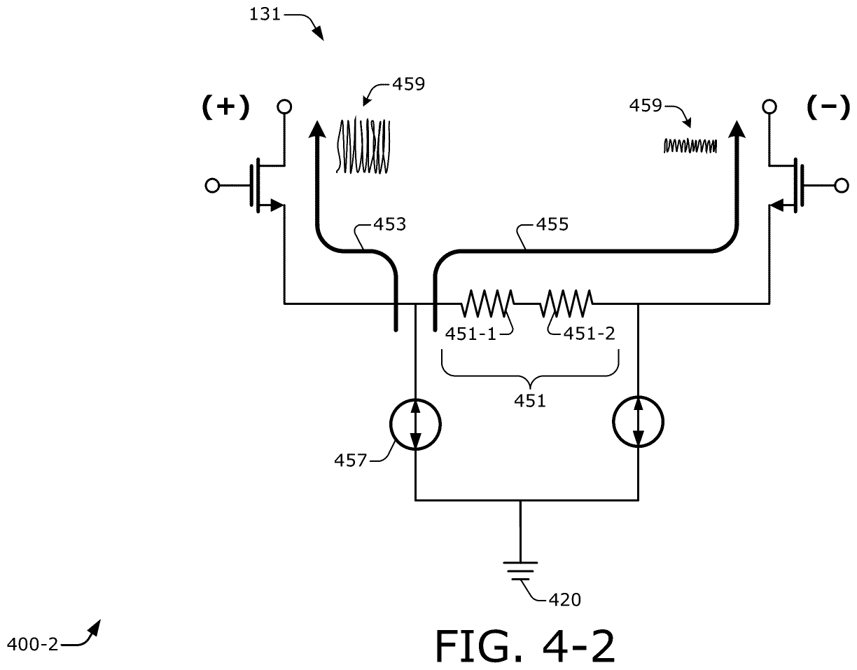

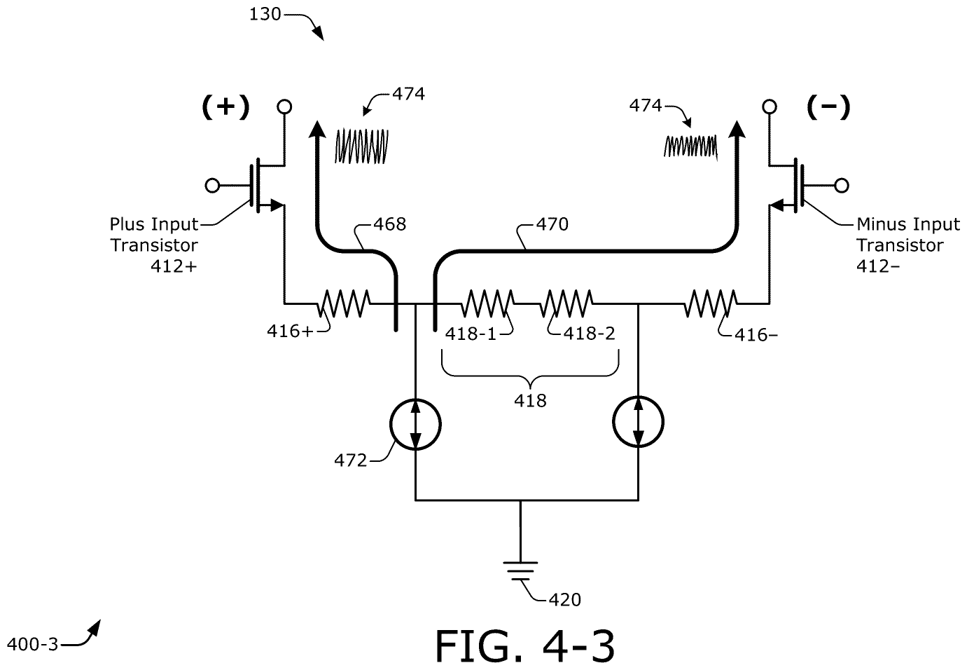

FIG. 4-1 is a circuit diagram 400-1 of an example voltage-to-current converter 130 that illustrates an example first aspect 402-1 that can reduce noise in an output signal 406 and an example second aspect 402-2 that can reduce nonlinearity in the output signal 406. An input signal 404 for the voltage-to-current converter 130 is also shown. In a differential environment, the input signal 404 includes a plus input signal 404+ and a minus input signal 404−. Similarly, the output signal 406 includes a plus output signal 406+ and a minus output signal 406−. In example operations, the voltage-to-current converter 130 receives a voltage-mode input signal 404 and produces a current-mode output signal 406.

In example implementations, the voltage-to-current converter 130 includes at least one input transistor 412, at least one current-source transistor 414, and one or more resistors. The input transistor 412 is an example of the input transistor 132 (of FIG. 1), and the current-source transistor 414 is an example of the current-source transistor 136 (of FIG. 1). The one or more resistors may be configured to operate as, or may be coupled into the circuit as, at least one degeneration resistor 134 (of FIG. 1). As shown in FIG. 4-1, the voltage-to-current converter 130 includes a plus input transistor 412+, a minus input transistor 412−, a plus current-source transistor 414+ (plus CS transistor 414+), and a minus current-source transistor 414− (minus CS transistor 414−). The voltage-to-current converter 130 also includes a plus resistor 416+, a minus resistor 416−, and a resistor 418 (e.g., a first resistor 418-1 and a second resistor 418-2 in a central or middle degeneration resistor area). The plus current-source transistor 414+ is coupled between the plus input transistor 412+ and a power distribution node 420. The minus current-source transistor 414− is coupled between the minus input transistor 412− and the power distribution node 420.

The input transistor 412 can be configured to operate as a transconductance device that converts voltage-mode signaling to current-mode signaling (e.g., the input transistor 412 may be realized as at least one transconductance transistor). Additionally or alternatively, the input transistor 412 can be configured to operate as an amplification device (e.g., the input transistor 412 may be realized as at least one amplification transistor). An amplification transistor may have a gain that can change a voltage level, a current magnitude, or an amplitude of a signal generally. A gain ratio may be less than one, more than one, or one; thus, an amplification transistor may have a unit gain in some circumstances.

In the illustrated circuit, the power distribution node 420 is shown as a ground; however, a power distribution node can instead be a supply voltage rail (not shown). With the depicted NMOS implementation of the transistors, the current-source transistor 414 can be coupled to a ground (e.g., via a source terminal thereof), and the input transistor 412 can be coupled to a supply voltage rail (e.g., via a drain terminal thereof). In a PMOS implementation of a V2I converter, in contrast, the depicted power distribution node 420 that is coupled to the current-source transistors can be a supply voltage rail, and the input transistors can be coupled to a ground via a channel terminal that is opposite to a channel terminal that is coupled to a degeneration resistor.

Further, as shown with respect to the example first aspect 402-1, the plus resistor 416+ can be coupled between the plus input transistor 412+ and the plus current-source transistor 414+ via a respective channel terminal of each of the plus transistors. The minus resistor 416− can be coupled between the minus input transistor 412− and the minus current-source transistor 414− via a respective channel terminal of each of the minus transistors. The resistor 418 (e.g., which may be realized as two or more resistors, like a resistor 418-1 and a resistor 418-2) can be coupled between the plus resistor 416+ and the minus resistor 416−. Additionally, the plus resistor 416+, the resistor 418, and the minus resistor 416− can be coupled together in series between the plus input transistor 412+ and the minus input transistor 412− via a respective channel terminal of each of the input transistors, such as via two respective source terminals as shown for an NMOS implementation.

As illustrated in FIG. 4-1, the voltage-to-current converter 130 can include at least one conductive path 424 coupled between the plus input transistor 412+ and the minus input transistor 412− (e.g., between respective channel terminals thereof, such as between respective source terminals as shown). The conductive path 424 can also be coupled between the plus current-source transistor 414+ and the minus current-source transistor 414− (e.g., between respective channel terminals thereof, such as between respective drain terminals as shown for an NMOS implementation). The conductive path 424 can include at least one wire, metal trace, metal layer portion, etc. that can conduct electrical current. The conductive path 424 can include one or more components, such as at least one resistor. As shown, by way of example only, the conductive path 424 may include at least one resistor 418, such as a first resistor 418-1 and a second resistor 418-2. The conductive path 424 may, however, include more, fewer, and/or different component(s).

The resistor 418 can be coupled between the plus current-source transistor 414+ and the minus current-source transistor 414−, such as between respective channel terminals thereof. For example, the resistor 418 can be coupled between a drain terminal of the plus current-source transistor 414+ and a drain terminal of the minus current-source transistor 414− for an example NMOS implementation. As shown, the plus resistor 416+ can be coupled between a source terminal of the plus input transistor 412+ and the drain terminal of the plus current-source transistor 414+. The minus resistor 416− can be coupled between a source terminal of the minus input transistor 412− and the drain terminal of the minus current-source transistor 414−.

The current-source (CS) transistors can be configured as current sources or operated as current sources. This is indicated at 422+ and 422− where a current source symbol and an associated parasitic resistance are depicted to illustrate an example operational state of the plus current-source transistor 414+ and the minus current-source transistor 414−, respectively. Accordingly, some implementations of the voltage-to-current converter 130 are depicted with at least one current source 422, such as a plus current source 422+ and a minus current source 422−.

Certain components of FIG. 4-1 are labeled with an “additional” descriptive term for clarity but by way of example only. For instance, the “plus input transistor” refers to a transistor that can correspond to a plus portion of a differential signal and that may accept or receive a plus input signal 404+ as part of an operation of the voltage-to-current converter 130. As described above, the input transistor 412 may also be referred to as a transconductance transistor or an amplification transistor. Similarly, a “minus current-source transistor” refers to a transistor that can correspond to a minus portion of the differential signal and that may function as a current source during at least part of the operation of the voltage-to-current converter 130.

These terms are, however, used for clarity only. An input transistor may alternatively be referred to as, e.g., a main transistor, an amplification transistor, or a transconductance transistor. Thus, the input transistor may be implemented as a transconductance device that may include at least one transconductance transistor and that may or may not apply a non-unitary gain to an incoming signal. In some cases, an amplification or transconductance transistor may not provide a gain or may have a unity gain. Generally, the plus input transistor and the minus input transistor may instead be referred to as a transistor that is distinguished or differentiated from other transistors using a numerical identifier, for example, as a first transistor and a second transistor, respectively. Similarly, the plus current-source transistor and the minus current-source transistor may instead be referred to, for example, as a third transistor and a fourth transistor, respectively.

FIG. 4-2 is a circuit diagram 400-2 of an example voltage-to-current converter 131 that illustrates an example signal-noise-routing paradigm based on at least one position of at least one degeneration resistor of the depicted voltage-to-current converter 131. FIG. 4-3 is a circuit diagram 400-3 of an example voltage-to-current converter 130 that illustrates another example signal-noise-routing paradigm based on at least one different position of at least one degeneration resistor of the depicted voltage-to-current converter 130 to facilitate understanding the example first aspects 402-1 (of FIG. 4-1) that are described herein. In the two illustrated voltage-to-current converters of FIGS. 4-2 and 4-3, the current sources are represented by noise sources for this noise-related signal analysis. Each voltage-to-current converter includes one or more degeneration resistors.

In the example voltage-to-current converter 131 of FIG. 4-2, two degeneration resistors are shown: a resistor 451-1 and a resistor 451-2. The resistor 451-1 and the resistor 451-2 may, however, be implemented as a resistor 451, and vice versa. Two noise-related current flows are shown. Each current flow 453 and 455 is injected into an output signal by noise caused by a current source that is depicted as a noise source 457, which corresponds to the “plus” side of the differential circuit in this example. The current, and thus the noise, is appreciably greater in the current flow 453 relative to the noise level of the current flow 455. This is illustrated with noise symbols 459 near each current flow. This occurs in part because the greater current flow 453 takes the fork or path to the left versus the right (as depicted) because the resistors 451-1 and 451-2 deter current flow to the minus side of the circuit in the path on the right. As a result, the noise is appreciably uncorrelated between the plus and minus portions of the differential output signal. Accordingly, a relatively greater amount of noise is produced in the output signal, at least when the differential plus and minus signals are resolved.

In the example voltage-to-current converter 130 of FIG. 4-3, four degeneration resistors are shown: a resistor 416+, a resistor 416−, a resistor 418-1, and a resistor 418-2. The resistor 418-1 and the resistor 418-2 may, however, be implemented as a resistor 418, and vice versa. Two noise-related current flows are shown. Each current flow 468 and 470 is injected into an output signal by noise caused by a current source that is depicted as a noise source 472, which corresponds to the “plus” side of the differential circuit in this example. The current magnitude, and thus amplitudes of the noise as indicated by the noise symbols 474, is noticeably closer between the two current flows 468 and 470 in the voltage-to-current converter 130 relative to the corresponding two noise values as indicated by the noise symbols 459 of the current flows 453 and 455 of the voltage-to-current converter 131 in FIG. 4-2.

This occurs in part because the current emanating from the noise source 472 on the left is confronted with resistance values in both paths—toward the plus input transistor 412+ and toward the minus input transistor 412−. As a result, the noise is appreciably more correlated between the plus and minus portions of the differential output signal as indicated by the noise symbols 474 that are depicted as being relatively closer in magnitude to each other in FIG. 4-3 as compared to the noise symbols 459 in FIG. 4-2. Accordingly, the two noise levels in the plus and minus portions of the differential output signal of the voltage-to-current converter 130 can cancel out a relatively greater amount of noise when the differential signals are resolved. The noise symbols 459 and 474 are illustrated at certain relative amplitudes by way of example only and are not necessarily depicted to scale.

In other words, the noise is more evenly distributed or split between the plus and minus portions of the input transistors with the voltage-to-current converter 130 in FIG. 4-3 based on the principles that are described herein for the example first aspects 402-1 (of FIG. 4-1). Due to the common-mode signaling, the split noise levels of the voltage-to-current converter 130 in FIG. 4-3 can cancel each other more as compared to the noise that predominantly flows along a single transistor path with the voltage-to-current converter 131 in FIG. 4-2. In these manners, including a resistor 416+ between the plus input transistor 412+ and the plus current-source transistor or a resistor 416− between the minus input transistor 412− and the minus current-source transistor can reduce an amount of noise that is produced by the voltage-to-current converter 130. Thus, these techniques can reduce an amount of noise that may be injected into downstream components of a communication chain, such as a mixer circuit.

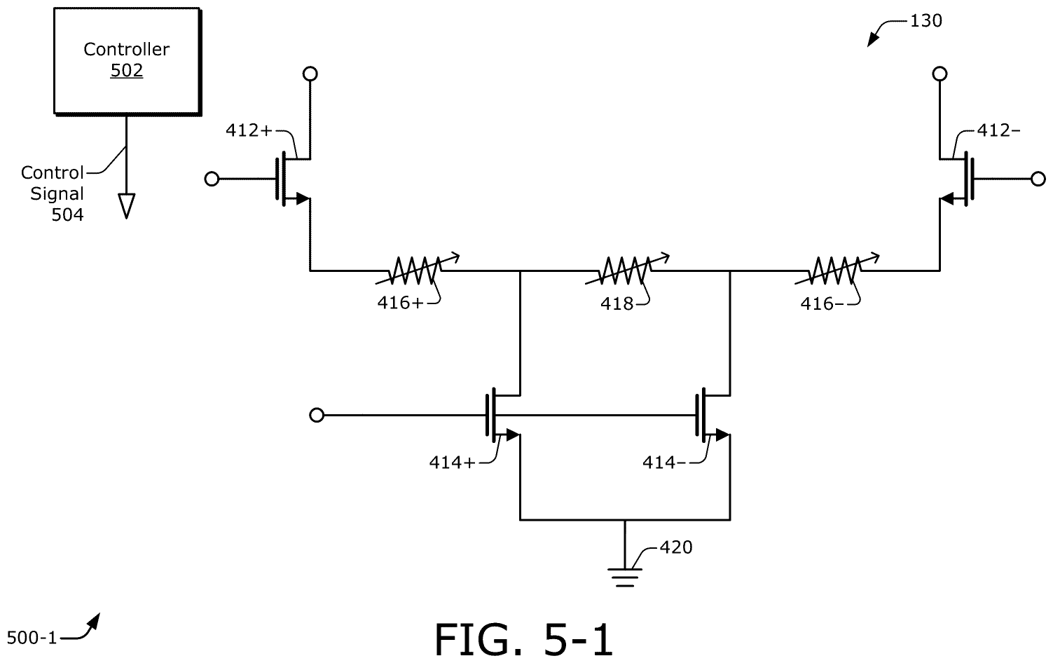

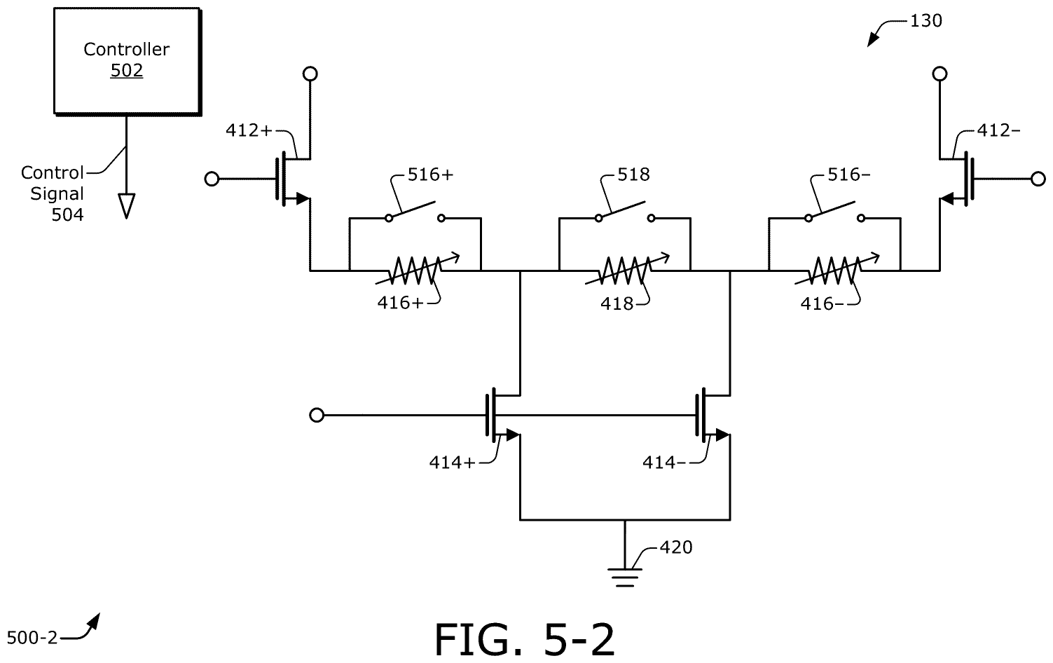

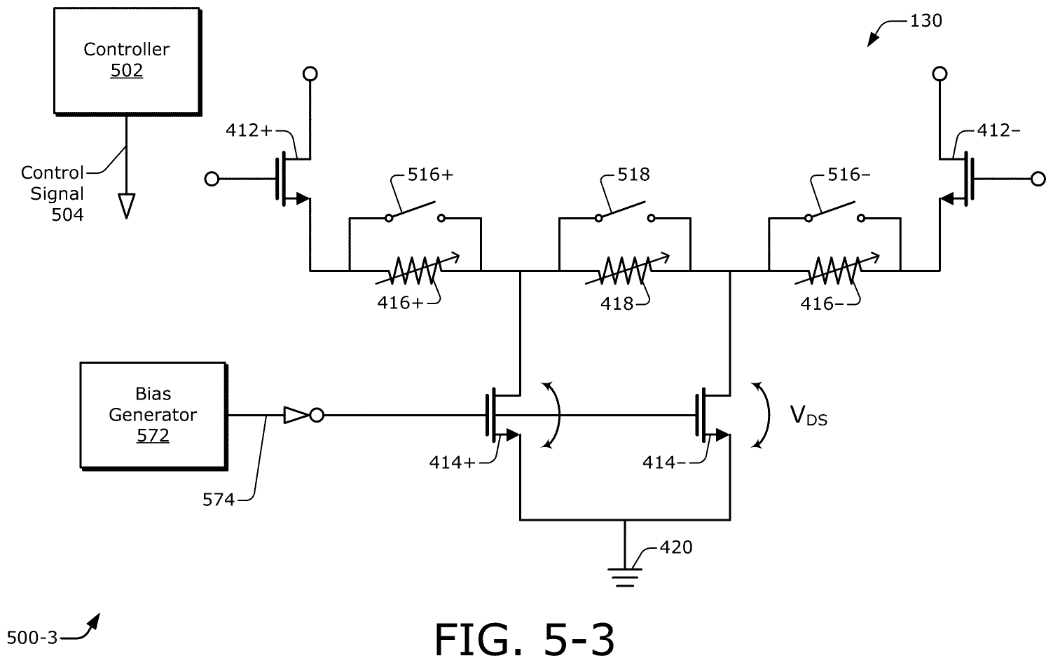

FIGS. 5-1 to 5-3 are circuit diagrams 500-1 to 500-3 illustrating multiple example implementations of a voltage-to-current converter 130. In the circuit diagram 500-1 of FIG. 5-1, each of the degeneration resistors is realized with at least one adjustable resistor, as indicated by the arrow through each respective resistor symbol. For example, the plus resistor 416+ can include a plus adjustable resistor, and the minus resistor 416− can include a minus adjustable resistor. Similarly, the resistor 418 can include an adjustable resistor. Each adjustable resistor may, for instance, be formed using multiple non-adjustable resistors that are coupled in series with a switch or in parallel with a switch. The switch can be placed in an open state for a parallel-connected switch or in a closed state for a series-connected switch to activate or include the respective corresponding resistor in a total resistance of the adjustable resistor. In some cases, an adjustable resistor can be implemented using a bank of resistors with associated respective switches.

By using at least one adjustable resistor for a degeneration resistor of the voltage-to-current converter 130, the voltage-to-current converter can be tuned to decrease noise to a greater extent, potentially at the expense of decreasing linearity. Alternatively, the voltage-to-current converter 130 can be tuned to increase linearity to a greater extent, potentially at the expense of increasing noise. Generally, the higher a resistance value of a plus resistor 416+ or a minus resistor 416− is relative to a resistance value of the “central” resistor 418, the lower the linearity is of the voltage-to-current converter 130.

The adjustable resistances of the degeneration resistors can be adjusted or established by a controller 502. The controller 502 can be, for instance, part of any portion of the wireless interface device 120 (e.g., of FIGS. 1 and 2), such as the communication processor 124 or a portion in which the voltage-to-current converter 130 is located. In operation, the controller 502 issues at least one control signal 504 to adjust at least one resistance of at least one resistor (e.g., by opening or closing at least one switch associated with the at least one resistor) of the degeneration resistors of the voltage-to-current converter 130. The resistances can be adjusted depending on if noise reduction or nonlinearity reduction is more important in a given operational environment. As illustrated, each of the degeneration resistors may be implemented as an architected resistor, instead of a parasitic or unintended resistance. Although each of the depicted degeneration resistors is shown as an adjustable resistor, fewer than all (including none) of the degeneration resistors may be implemented to be adjustable. Further, a degeneration resistor may include an adjustable resistance/resistor and a nonadjustable resistance/resistor.

In the circuit diagram 500-2 of FIG. 5-2, each of the degeneration resistors is coupled in parallel with a respective switch. For example, the plus resistor 416+ can be coupled in parallel with a plus switch 516+, and the minus resistor 416− can be coupled in parallel with a minus switch 516−. Similarly, the resistor 418 can be coupled in parallel with a switch 518. In an open state, a respective switch has relatively little impact on the functionality of the respective resistor to which it is coupled together in parallel. In a closed state, however, a respective switch can at least one of short or bypass the respective resistor responsive to the switch being in the closed state. Although not shown, the switch 518 may also be coupled in parallel with a non-adjustable resistor 418. This configuration in which a non-adjustable resistor is coupled in parallel with a switch (e.g., a plus switch 516+ or a minus switch 516−) is also applicable to the plus resistor 416+ and the minus resistor 416−.

Thus, a parallel switch can “remove” a resistor, including an adjustable or a non-adjustable resistor, from the functionality of a circuit by being closed. This can enable the controller 502 to focus operation of the voltage-to-current converter 130 quickly or more fully, including both quickly and more fully, on noise reduction or nonlinearity reduction depending on current operational parameters. Although each of the depicted degeneration resistors is shown being coupled in parallel with a respective switch, fewer than all (including none) of the degeneration resistors may be coupled in parallel with a switch.

In the circuit diagram 500-3 of FIG. 5-3, each of the degeneration resistors is coupled in parallel with a respective switch, and each of the degeneration resistors is implemented to provide an adjustable resistance. The various implementations for degeneration resistors provide example first aspects 402-1 (of FIG. 4-1) of described implementations. In example second aspects 402-2 (also of FIG. 4-1) of described implementations, the transistors of the current sources can be biased to increase linearity of the voltage-to-current converter 130. To do so, a bias generator 572 can apply a bias signal 574 to a control input (e.g., a gate terminal) of the plus current-source transistor 414+ or the minus current-source transistor 414−, including to control inputs of both transistors.

In example implementations, the bias generator 572 biases the plus and minus current-source transistors 414+ and 414− into a triode region of operation, instead of a saturation region. In a saturation region of operation, as the voltage across the transistor changes, the current flowing through it remains substantially constant. For example, the current may deviate by no more than 10%, or even by no more than 5%, while the transistor is in saturation as the voltage across the channel terminals of the transistor fluctuates. In contrast, the current of the transistor can deviate more significantly in response to changes in voltage across the transistor while in the triode mode of operation.

In some cases, a drain-to-source voltage V_{DS} (e.g., for FET implementations) of the current-source transistors is maintained at a level that enables the tail current of the voltage-to-current converter 130 to increase as the “main” or “amplification” current of the input transistor decreases. The current of the voltage-to-current converter 130 can therefore be more balanced to counteract current clipping in the input transistors. This biasing technique can improve, for instance, Adjacent Channel Leakage Ratio (ACLR).

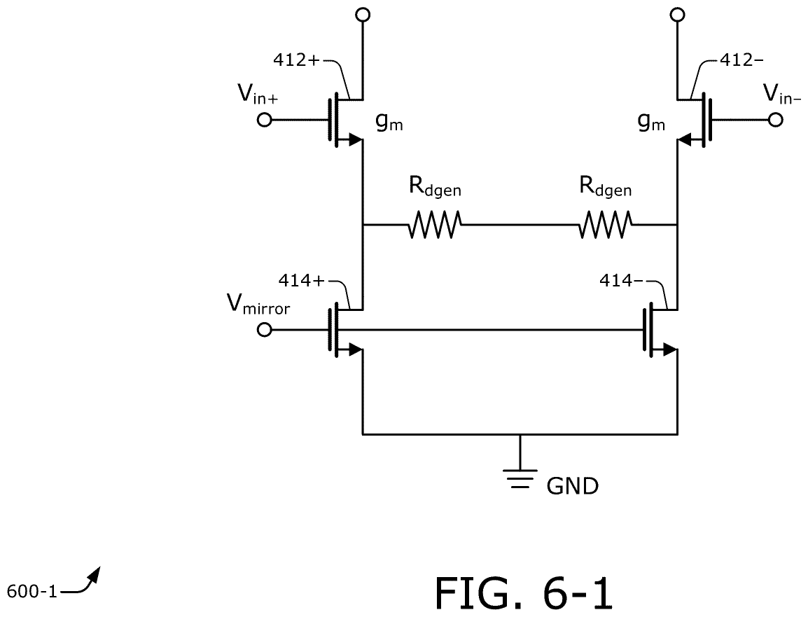

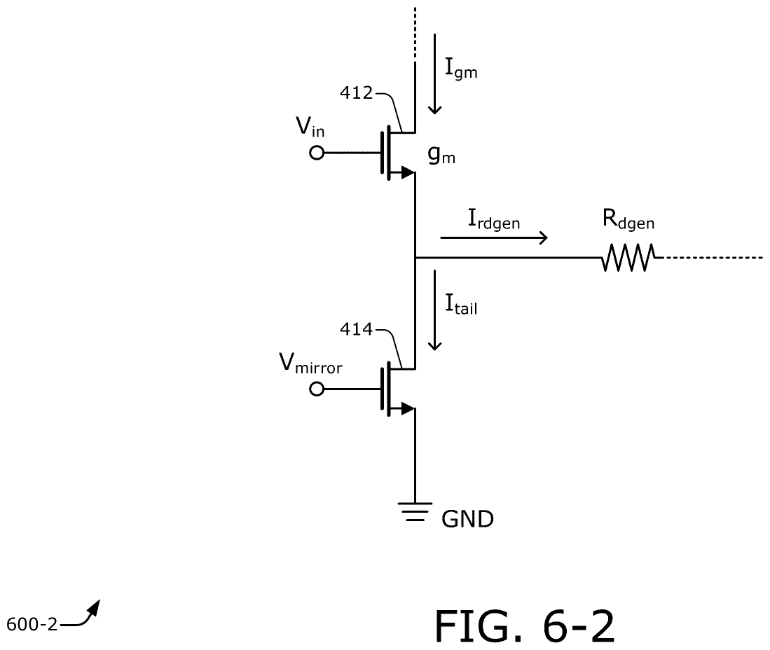

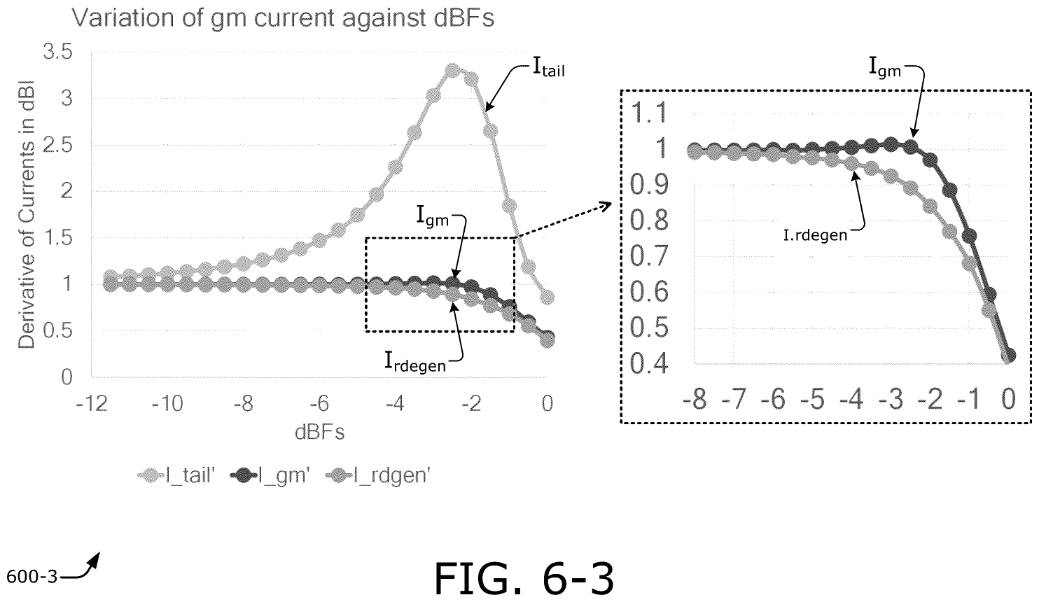

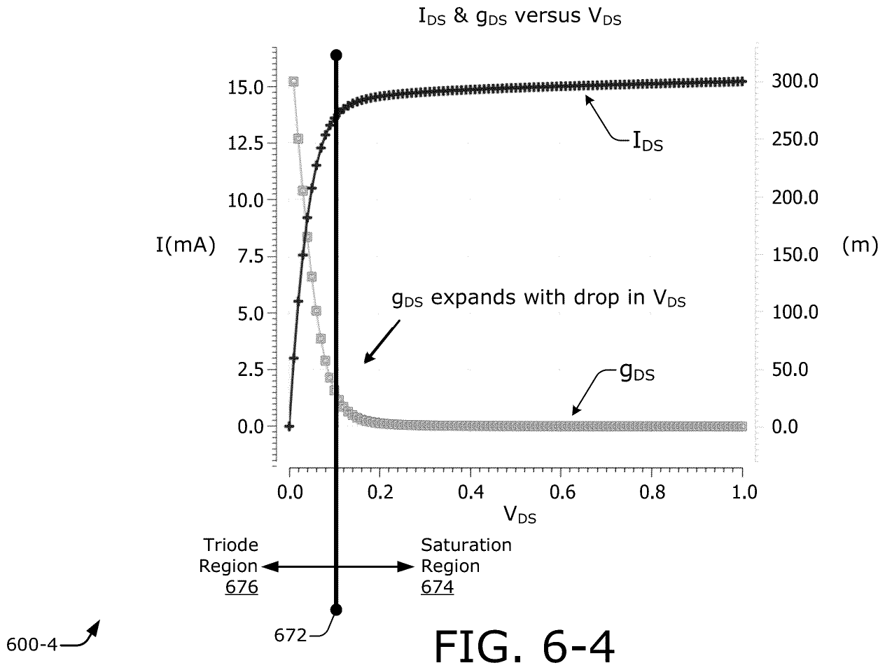

FIGS. 6-1 to 6-4 are diagrams 600-1 to 600-4, respectively, illustrating multiple example implementations of a voltage-to-current converter in accordance with at least the example second aspects 402-2 (of FIG. 4-1). A circuit diagram 600-1 of FIG. 6-1 depicts a voltage-to-current converter that includes at least one degeneration resistor R_{dgen} coupled between the two current-source transistors 414+ and 414−. The two input transistors 412+ and 412− can provide amplification and may be referred to as amplification or main transistors. Although not shown in FIG. 6-1, the bias generator 572 can produce the bias signal 574 (both of FIG. 5-2) as the mirror voltage (Vₘᵢᵣᵣₒᵣ) to bias the two current-source transistors 414+ and 414−. The transconductance Gₘ of the voltage-to-current converter can be linearized using resistive degeneration. Here, the resistively degenerated transconductance Gₘ can be given by:

$${G}_{m} = \frac{{g}_{m}}{1 + {g}_{m} * {R}_{dgen}} ,$$

wherein “gₘ” is the transconductance of an input transistor 412. Thus, a higher loop gain (gₘR_{dgen}) reduces variations in the transconductance (Gₘ) over the input signal.

Tail current expansion from the current sources (of the current-source transistors 414+ and 414−) can contribute to the output current. Accordingly, tail current bias can also contribute to signal current (e.g., due to Vds-Ids nonlinearity) in addition to providing the DC bias current. Responsive to the gₘ of the input transistors 412+ and 412− starting to compress near a full-scale signal, the tail current from the current sources can expand to compensate for the gₘ compression of the input transistors. Although the voltage-to-current converter of FIG. 6-1 omits a degeneration resistor that is coupled between a respective input transistor 412 and a respective current-source transistor 414 (e.g., between two plus transistors or two minus transistors like the plus resistor 416+ and the minus resistor 416− of FIG. 5-3), the principles and techniques of FIGS. 6-1 to 6-4 are also applicable to such circuits, including those of FIGS. 4-1, 4-3, and 5-1 to 5-3.

A circuit diagram 600-2 of FIG. 6-2 depicts a portion of a voltage-to-current converter (e.g., of FIG. 6-1) that illustrates three example currents: a gₘ current (I_{gm}) of an input transistor 412, a tail current (Iₜₐᵢₗ) of a current-source transistor 414, and a degeneration resistor current (I_{rdgen}) of a degeneration resistor R_{dgen}. These currents are used to described certain principles with reference to FIG. 6-3.

A diagram 600-3 of FIG. 6-3 depicts example graphs of the currents of FIG. 6-2. For each of the three currents, the graph on the left illustrates the derivative of the current in decibels (dBI) versus decibels relative to full scale (dBFs). This graph shows the variation of the gₘ current (I_{gm}) against decibels relative to full scale (dBFs). As the gₘ current (I_{gm}) starts to decrease, the tail current (Iₜₐᵢₗ) increases to compensate and thereby maintain the combined current across a wider signal input range. This is even clearer in the zoomed-in graph on the right. The gₘ current (I_{gm}) is maintained at a substantially constant level “longer” than is the degeneration resistor current (I_{rdgen}) due to the increased tail current (Iₜₐᵢₗ).

A diagram 600-4 of FIG. 6-4 depicts an example graph of I_{DS} versus V_{DS} and an example graph of gos versus V_{DS}. The g_{DS} values decrease relatively quickly as V_{DS} increases from zero until approximately 0.10 to 0.16 V_{DS}, and then the g_{DS} values become substantially constant with increasing V_{DS}. In contrast, the Ips values increase relatively quickly as V_{DS} increases from zero until approximately 0.10 to 0.18 V_{DS}, and then the I_{DS} values become substantially constant with increasing V_{DS}.

For certain example implementations, a transistor operational region demarcation 672 is depicted. An example saturation region 674 and an example triode region 676 are also depicted. The triode region 676 corresponds to relatively more rapid changes to the transistor current (I_{DS}), as well as the gps, as compared to the saturation region 674 in which these values are substantially constant as V_{DS} increases. It should be noted that the transistor operational region demarcation 672 may be established or located at a V_{DS} level that is slightly less than or greater than the one indicated and/or that the demarcation may be represented by a small range of V_{DS} values as the transistor transitions between the two regions. Further, a demarcation may have a different value for other circuits or other transistors.

With appropriate biasing, the tail current source can expand because of g_{DS} expansion when the tail current is driven in the triode region 676. Generally, g_{DS} expansion is the dual of gₘ expansion in, for example, class B/C voltage-mode amplifiers. As V_{GS} (gate-source voltage) increases on a transistor (e.g., an FET), then I_{DS} increases through the transistor. In some cases, a tail current source can behave like a “Class-B” amplifier. With Class-B amplifiers, the transconductance gₘ expands when V_{GS} (gate-source voltage) swings are large, but the g_{DS} expands when V_{DS} (drain-source voltage) swings are large.

Using these properties, the Gm current of the voltage-to-current converter may be linearized. To do so, the expansion of the gₘ of the tail current source can be aligned with the compression of the gₘ of the input transistor. Although this biasing point or biasing range may change somewhat over process or temperature, the bias value can be static relative to the input signals of the voltage-to-current converter. In other words, enhancing or even optimizing the bias setting may involve testing due to process variability or may involve relatively slow or infrequent update changes during operation due to temperature variances, but the voltage bias setting need not be tied to, or required to track, a rapidly fluctuating input signal.

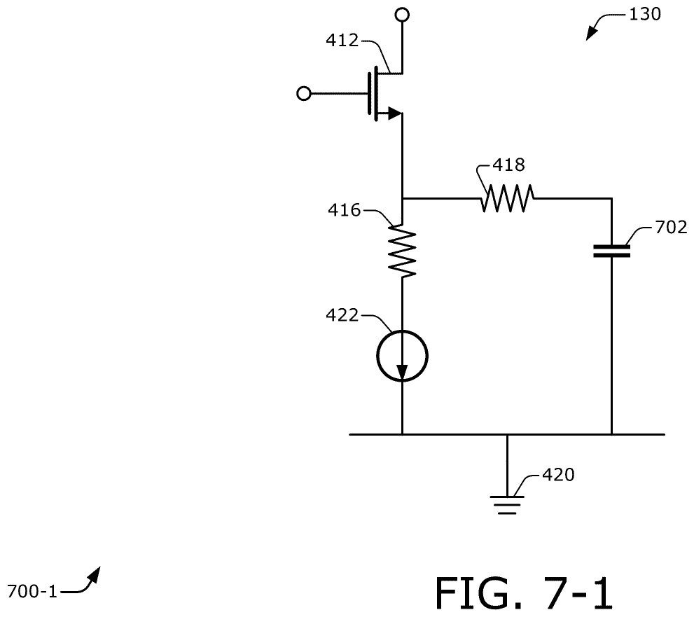

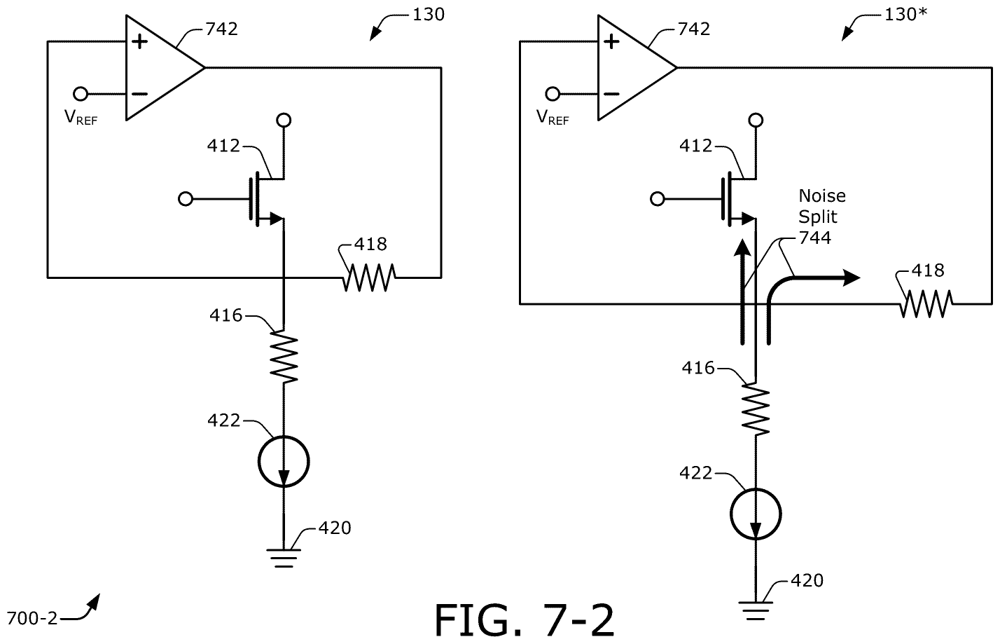

FIGS. 7-1 and 7-2 are circuit diagrams 700-1 and 700-2 illustrating multiple example implementations of a voltage-to-current converter in accordance with the example first aspects and the example second aspects for single-ended environments. In FIG. 7-1, the voltage-to-current converter 130 includes a capacitor 702 coupled between a resistor 418 and a power distribution node 420 (or power supply network node 420), such as the ground. The resistor 418 may be implemented as an adjustable resistor 418, which is described above with reference to FIG. 5-1. Further, a switch 518 may be coupled in parallel with the adjustable resistor 418 (or a non-adjustable resistor 418) as described above with reference to FIG. 5-2. The current source 422 can be implemented with a current-source transistor 414. The current-source transistor 414 can be biased in the triode region 676 as described above with reference to FIGS. 5-3 and 6-1 to 6-4 to linearize the output current. The capacitor 702 may, however, be relatively large in some circumstances and therefore expensive or difficult to implement. To avoid using such a large capacitor, an operational amplifier (op amp) may be used in the circuit instead.

In FIG. 7-2, the voltage-to-current converter 130 includes an op amp 742, as depicted on the left of the circuit diagram 700-2. The resistor 418 is coupled between the current source 422 and an output of the op amp 742. A first input (e.g., a minus input) of the op amp 742 is tied to a reference voltage (V_{REF}). A second input (e.g., a plus input) of the op amp 742 is coupled to a node that corresponds to a terminal of the resistor 416, a terminal of the resistor 418, and a terminal of the input transistor 412. As indicted on the right of the circuit diagram 700-2 for the voltage-to-current converter 130*, the noise injected by the current source 422 is split between the input transistor 412 and the resistor 418. The resistance value of the resistor 418 can be adjusted to change how much noise is reduced. Thus, although not explicitly indicated, the resistors 416 and 418 of FIGS. 7-1 and 7-2 may be adjustable or may be coupled in parallel with at least one switch to adjust the resistance values after the circuit of the voltage-to-current converter is fabricated or already in use.

Each transistor as described herein or depicted in the various drawings may be realized with any one or more of multiple transistor types. Examples transistor types include a field effect transistor (FET), a junction FET (JFET), a metal-oxide-semiconductor FET (MOSFET), a bipolar junction transistor (BJT), an insulated-gate bipolar transistor (IGBT), and so forth. Manufacturers may, for instance, fabricate FETs as n-channel or p-channel transistor types and may fabricate BJTs as NPN or PNP transistor types. Each illustrated or described transistor may further be realized with two or more transistors in series or in parallel.

Each transistor may include at least one control terminal and one or more channel terminals. With an FET transistor, a control terminal can correspond to a gate terminal, and a channel terminal can correspond to a source terminal or a drain terminal. With a BJT transistor, a control terminal can correspond to a base terminal, and a channel terminal can correspond to an emitter terminal or a collector terminal.

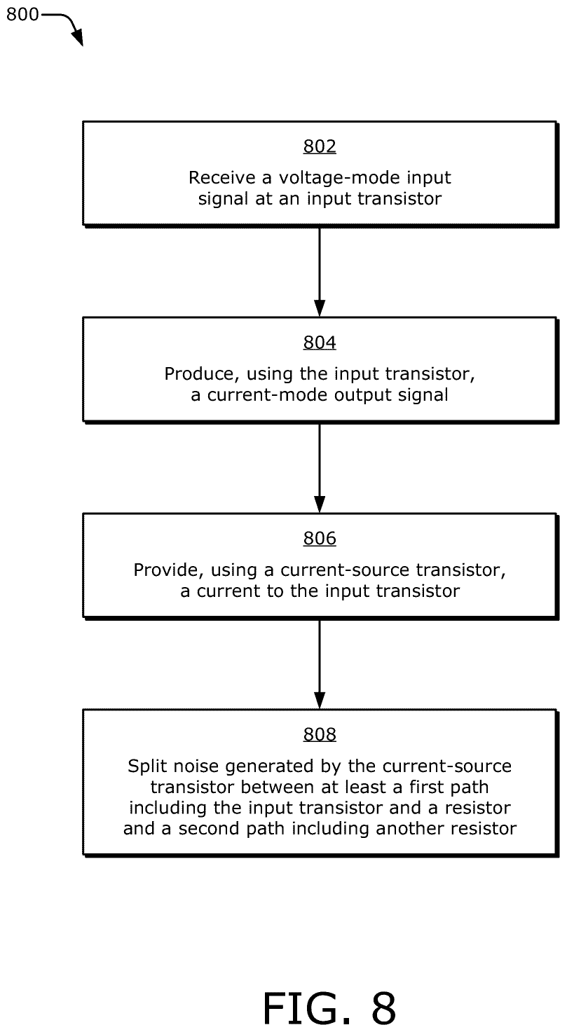

FIG. 8 is a flow diagram illustrating an example process 800 for performing a voltage-to-current conversion procedure or for operating a voltage-to-current converter. The process 800 includes four blocks 802-808 that specify operations that can be performed for a method. However, operations are not necessarily limited to the order shown in the figures or described herein, for the operations may be implemented in alternative orders or in fully or partially overlapping manners. Also, more, fewer, and/or different operations may be implemented to perform a respective process or an alternative process.

In example implementations, operations represented by the illustrated blocks of each process may be performed by an electronic device, such as the electronic device 102 of FIG. 1 or the wireless interface device 120 thereof. More specifically, the operations of the respective processes may be performed by a voltage-to-current converter 130 of a transceiver 126 or an RF front-end 128. Although some of the description herein focusses on a voltage-to-current converter that operates on differential signals, the described principles (e.g., corresponding to devices, circuitry, techniques, and processes) are not so limited. These principles are also applicable to single-ended signaling.

At block 802, a voltage-mode input signal is received at an input transistor. For example, a voltage-to-current converter 130 can receive a voltage-mode input signal 404 at an input transistor 412. For instance, a plus input transistor 412+ may receive a plus input signal 404+ having voltage-mode signaling at a control terminal of the transistor (e.g., at a gate terminal of an FET).

At block 804, using the input transistor, a current-mode output signal is produced. For example, the voltage-to-current converter 130 can produce, using the input transistor 412, a current-mode output signal 406. To do so, the plus input transistor 412+ may produce a plus output signal 406+ having current-mode signaling at a channel terminal of the transistor (e.g., at a drain terminal of an n-type FET).

At block 806, using a current-source transistor, a current is provided to the input transistor. For example, the voltage-to-current converter 130 can provide, using a current-source transistor 414, a current (e.g., corresponding to a current flow 468) to the input transistor 412. In some cases, a plus current-source transistor 414+ may provide a bias current to at least the plus input transistor 412+. Further, the plus current-source transistor 414+ may also provide a bias current to a minus input transistor 412−.

At block 808, noise generated by the current-source transistor is split between at least a first path including the input transistor and a resistor and a second path including another resistor. For example, the voltage-to-current converter 130 can split noise generated by the current-source transistor 414 between at least a first path including the input transistor 412 and a resistor 416 and a second path including another resistor. This may be performed at least partly by a node that joins the first path, the second path, and the plus current-source transistor 414+. The first path may include the plus input transistor 412+ and a plus resistor 416+. The second path may include at least a minus resistor 416−. The second path may also include a resistor 418 (e.g., a first resistor 418-1 and a second resistor 418-2); thus, the second path may include a conductive path 424. Any one or more of these resistors may be adjustable. Additionally or alternatively, any one or more of these resistors may be coupled in parallel with a switch 516 or 518.

In some implementations, the current-source transistor is biased in a triode region of transistor operation during at least part of the providing of the current to the input transistor. For example, the voltage-to-current converter 130 can bias the current-source transistor 414 in a triode region 676 of transistor operation during at least part of the providing of the current to the input transistor 412. Here, a bias generator 572 may use a bias signal 574 to bias a plus current-source transistor 414+in the triode region 676 of operation for a transistor during at least part of the time that the plus current-source transistor 414+ is providing a bias current to the plus input transistor 412+.

### IMPLEMENTATION EXAMPLES

This section describes some aspects of example implementations and/or example configurations related to the apparatuses and/or processes presented above.

Example aspect 1: An apparatus comprising:
a voltage-to-current converter comprising:
   a plus input transistor;
   a minus input transistor;
   a plus current-source transistor coupled between the plus input transistor and a power distribution node;
   a minus current-source transistor coupled between the minus input transistor and the power distribution node;
   a plus resistor coupled between the plus input transistor and the plus current-source transistor; and
   a minus resistor coupled between the minus input transistor and the minus current-source transistor.

Example aspect 2: The apparatus of example aspect 1, wherein the voltage-to-current converter comprises:
a plus switch coupled in parallel with the plus resistor.

Example aspect 3: The apparatus of example aspect 2, wherein:
the plus switch is configured to at least one of short or bypass the plus resistor responsive to being in a closed state.

Example aspect 4: The apparatus of any one of the preceding example aspects, wherein:
the plus resistor comprises a plus adjustable resistor; and
the minus resistor comprises a minus adjustable resistor.

Example aspect 5: The apparatus of example aspect 4, wherein the voltage-to-current converter comprises:
a plus switch coupled in parallel with the plus adjustable resistor; and
a minus switch coupled in parallel with the minus adjustable resistor.

Example aspect 6: The apparatus of any one of the preceding example aspects, wherein the voltage-to-current converter comprises:
a conductive path coupled between the plus resistor and the minus resistor.

Example aspect 7: The apparatus of example aspect 6, wherein the voltage-to-current converter comprises:
a resistor coupled between the plus resistor and the minus resistor along the conductive path.

Example aspect 8: The apparatus of example aspect 7, wherein:
the plus resistor, the resistor, and the minus resistor are coupled together in series between the plus input transistor and the minus input transistor.

Example aspect 9: The apparatus of example aspect 7 or 8, wherein:
the resistor is coupled between the plus current-source transistor and the minus current-source transistor.

Example aspect 10: The apparatus of any one of example aspects 7 to 9, wherein the voltage-to-current converter comprises:
a switch coupled in parallel with the resistor.

Example aspect 11: The apparatus of any one of example aspects 7 to 10, wherein the voltage-to-current converter comprises:
a plus switch coupled in parallel with the plus resistor; and
a minus switch coupled in parallel with the minus resistor.

Example aspect 12: The apparatus of any one of example aspects 7 to 11, wherein:
the plus resistor comprises a plus adjustable resistor;
the minus resistor comprises a minus adjustable resistor; and
the resistor comprises an adjustable resistor.

Example aspect 13: The apparatus of example aspect 12, wherein the voltage-to-current converter comprises:
a plus switch coupled in parallel with the plus adjustable resistor;
a minus switch coupled in parallel with the minus adjustable resistor; and
a switch coupled in parallel with the adjustable resistor.

Example aspect 14: The apparatus of any one of the preceding example aspects, wherein the voltage-to-current converter comprises:
a resistor coupled between the plus current-source transistor and the minus current-source transistor.

Example aspect 15: The apparatus of example aspect 14, wherein:
the resistor is coupled between a channel terminal of the plus current-source transistor and a channel terminal of the minus current-source transistor.

Example aspect 16: The apparatus of example aspect 15, wherein:
the plus resistor is coupled between a channel terminal of the plus input transistor and the channel terminal of the plus current-source transistor; and
the minus resistor is coupled between a channel terminal of the minus input transistor and the channel terminal of the minus current-source transistor.

Example aspect 17: The apparatus of example aspect 16, wherein:
the channel terminal of the plus current-source transistor comprises a drain terminal of the plus current-source transistor;
the channel terminal of the minus current-source transistor comprises a drain terminal of the minus current-source transistor;
the channel terminal of the plus input transistor comprises a source terminal of the plus input transistor; and
the channel terminal of the minus input transistor comprises a source terminal of the minus input transistor.

Example aspect 18: The apparatus of any one of the preceding example aspects, wherein:
the plus input transistor, the plus resistor, and the plus current-source transistor are coupled together in series between the power distribution node and another power distribution node.

Example aspect 19: The apparatus of example aspect 18, wherein:
the power distribution node comprises a ground; and
the other power distribution node comprises a voltage supply rail.

Example aspect 20: The apparatus of example aspect 1, wherein:
the plus input transistor is configured to convert a voltage-mode signal received at a control terminal of the plus input transistor to produce a current-mode signal at a channel terminal of the plus input transistor.

Example aspect 21: The apparatus of any one of the preceding example aspects, wherein:
the plus current-source transistor is configured to be biased in a triode region of transistor operation.

Example aspect 22: The apparatus of example aspect 21, further comprising:
a controller coupled to the voltage-to-current converter, the controller configured to bias the plus current-source transistor in the triode region of transistor operation to reduce nonlinearity of an output signal of the voltage-to-current converter.

Example aspect 23: The apparatus of any one of the preceding example aspects, wherein:
the plus current-source transistor is configured to operate as a current source with respect to at least the plus input transistor.

Example aspect 24: The apparatus of example aspect 23, wherein the plus current-source transistor is configured to:
produce an output current; and
adjust the output current dynamically responsive to voltage swings created by the plus input transistor.

Example aspect 25: The apparatus of example aspect 24, wherein the plus current-source transistor is configured to:
adjust the output current dynamically to counteract clipping experienced by the plus input transistor.

Example aspect 26: The apparatus of any one of the preceding example aspects, further comprising:
a digital-to-analog converter;
a base-band filter coupled between the digital-to-analog converter and the voltage-to-current converter; and
a mixer,
wherein the voltage-to-current converter is coupled between the base-band filter and the mixer.

Example aspect 27: An apparatus comprising:
a voltage-to-current converter comprising:
   a plus input transistor;
   a minus input transistor;
   a plus current-source transistor coupled between the plus input transistor and a power distribution node;
   a minus current-source transistor coupled between the minus input transistor and the power distribution node;
   means for reducing, in an output signal of the voltage-to-current converter, noise generated by the plus current-source transistor; and
   means for reducing, in the output signal of the voltage-to-current converter, noise generated by the minus current-source transistor.

Example aspect 28: A method for voltage-to-current conversion, the method comprising:
receiving a voltage-mode input signal at an input transistor;
producing, using the input transistor, a current-mode output signal;
providing, using a current-source transistor, a current to the input transistor; and
splitting noise generated by the current-source transistor between at least a first path including the input transistor and a resistor and a second path including another resistor.

Example aspect 29: The method of example aspect 28, further comprising:
biasing the current-source transistor in a triode region of transistor operation during at least part of the providing of the current to the input transistor.

Example aspect 30: An apparatus comprising:
a voltage-to-current converter comprising:
   a plus input transistor;
   a minus input transistor;
   a plus current-source transistor coupled between the plus input transistor and a power distribution node, the plus current-source transistor configured to be biased in a triode region of transistor operation during a voltage-to-current conversion procedure;
   a minus current-source transistor coupled between the minus input transistor and the power distribution node, the minus current-source transistor configured to be biased in the triode region of transistor operation during the voltage-to-current conversion procedure; and
   a conductive path coupled between the plus input transistor and the minus input transistor and between the plus current-source transistor and the minus current-source transistor.

Example aspect 31: An apparatus comprising:
a voltage-to-current converter comprising:
   a plus amplification transistor;
   a minus amplification transistor;
   a plus current-source transistor coupled between the plus amplification transistor and a power distribution node;
   a minus current-source transistor coupled between the minus amplification transistor and the power distribution node;
   a plus resistor coupled between the plus amplification transistor and the plus current-source transistor; and
   a minus resistor coupled between the minus amplification transistor and the minus current-source transistor.

Example aspect 32: The apparatus of example aspect 31 or any other example aspect, wherein the voltage-to-current converter comprises:
a plus switch coupled in parallel with the plus resistor.

Example aspect 33: The apparatus of example aspect 32 or any other example aspect, wherein:
the plus switch is configured to at least one of short or bypass the plus resistor responsive to being in a closed state.

Example aspect 34: The apparatus of example aspect 31 or any other example aspect, wherein:
the plus resistor comprises a plus adjustable resistor.

Example aspect 35: The apparatus of example aspect 34 or any other example aspect, wherein:
the minus resistor comprises a minus adjustable resistor.

Example aspect 36: The apparatus of example aspect 35 or any other example aspect, wherein the voltage-to-current converter comprises:
a plus switch coupled in parallel with the plus adjustable resistor; and
a minus switch coupled in parallel with the minus adjustable resistor.

Example aspect 37: The apparatus of example aspect 31 or any other example aspect, wherein the voltage-to-current converter comprises:
a resistor coupled between the plus resistor and the minus resistor.

Example aspect 38: The apparatus of example aspect 37 or any other example aspect, wherein:
the plus resistor, the resistor, and the minus resistor are coupled together in series between the plus amplification transistor and the minus amplification transistor.

Example aspect 39: The apparatus of example aspect 37 or any other example aspect, wherein:
the resistor is coupled between the plus current-source transistor and the minus current-source transistor.

Example aspect 40: The apparatus of example aspect 37 or any other example aspect, wherein the voltage-to-current converter comprises:
a switch coupled in parallel with the resistor.

Example aspect 41: The apparatus of example aspect 40 or any other example aspect, wherein the voltage-to-current converter comprises:
a plus switch coupled in parallel with the plus resistor; and
a minus switch coupled in parallel with the minus resistor.

Example aspect 42: The apparatus of example aspect 37 or any other example aspect, wherein:
the plus resistor comprises a plus adjustable resistor;
the minus resistor comprises a minus adjustable resistor; and
the resistor comprises an adjustable resistor.

Example aspect 43: The apparatus of example aspect 42 or any other example aspect, wherein the voltage-to-current converter comprises:
a plus switch coupled in parallel with the plus adjustable resistor;
a minus switch coupled in parallel with the minus adjustable resistor; and
a switch coupled in parallel with the adjustable resistor.

Example aspect 44: The apparatus of example aspect 31 or any other example aspect, wherein the voltage-to-current converter comprises:
a resistor coupled between the plus current-source transistor and the minus current-source transistor.

Example aspect 45: The apparatus of example aspect 44 or any other example aspect, wherein:
the resistor is coupled between a drain terminal of the plus current-source transistor and a drain terminal of the minus current-source transistor.

Example aspect 46: The apparatus of example aspect 45 or any other example aspect, wherein:
the plus resistor is coupled between a source terminal of the plus amplification transistor and the drain terminal of the plus current-source transistor; and
the minus resistor is coupled between a source terminal of the minus amplification transistor and the drain terminal of the minus current-source transistor.

Example aspect 47: The apparatus of example aspect 31 or any other example aspect, wherein:
the plus amplification transistor, the plus resistor, and the plus current-source transistor are coupled together in series between the power distribution node and another power distribution node.

Example aspect 48: The apparatus of example aspect 47 or any other example aspect, wherein:
the power distribution node comprises a ground; and
the other power distribution node comprises a voltage supply rail.

Example aspect 49: The apparatus of example aspect 31 or any other example aspect, wherein:
the plus amplification transistor is configured to amplify a voltage-mode signal received at a gate terminal of the plus amplification transistor to produce a current-mode signal at a drain terminal of the plus amplification transistor.

Example aspect 50: The apparatus of example aspect 31 or any other example aspect, wherein:
the plus current-source transistor is configured to be biased in a triode region of transistor operation.

Example aspect 51: The apparatus of example aspect 50 or any other example aspect, further comprising:
a controller coupled to the voltage-to-current converter, the controller configured to bias the plus current-source transistor in the triode region of transistor operation to reduce nonlinearities in an output signal of the voltage-to-current converter.

Example aspect 52: The apparatus of example aspect 31 or any other example aspect, wherein:
the plus current-source transistor is configured to operate as a current source with respect to at least the plus amplification transistor.

Example aspect 53: The apparatus of example aspect 52 or any other example aspect, wherein the plus current-source transistor is configured to:
produce an output current; and
adjust the output current dynamically responsive to voltage swings created by the plus amplification transistor.

Example aspect 54: The apparatus of example aspect 53 or any other example aspect, wherein the plus current-source transistor is configured to:
adjust the output current dynamically to counteract clipping experienced by the plus amplification transistor.

Example aspect 55: The apparatus of example aspect 31 or any other example aspect, further comprising:
a digital-to-analog converter;
a base-band filter coupled between the digital-to-analog converter and the voltage-to-current converter; and
a mixer, wherein the voltage-to-current converter is coupled between the mixer and the base-band filter.

### Conclusion

As used herein, the terms “couple,” “coupled,” or “coupling” refer to a relationship between two or more components that are in operative communication with each other to implement some feature or realize some capability that is described herein. The coupling can be realized using, for instance, a physical line, such as a metal trace or wire, or an electromagnetic coupling, such as with a transformer. A coupling can include a direct coupling or an indirect coupling. A direct coupling refers to connecting discrete circuit elements via a same node without an intervening element. An indirect coupling refers to connecting discrete circuit elements via one or more other devices or other discrete circuit elements, including two or more different nodes.

The term “node” (e.g., including a “first node” or a “power distribution network node”) represents at least a point of electrical connection between two or more components (e.g., circuit elements). Although at times a node may be visually depicted in a drawing as a single point, the node can represent a connection portion of a physical circuit or network that has approximately a same voltage potential at or along the connection portion between two or more components. In other words, a node can represent at least one of multiple points along a conducting medium (e.g., a wire or trace) that exists between electrically connected components. Similarly, a “terminal” or “port” may represent one or more points with at least approximately a same voltage potential relative to an input or output of a component (e.g., a transistor).

The terms “first,” “second,” “third,” and other numeric-related indicators are used herein to identify or distinguish similar or analogous items from one another within a given context—such as a particular implementation, a single drawing figure, a given component, or a claim. Thus, a first item in one context may differ from a first item in another context. For example, an item identified as a “first amplification transistor” in one context may be identified as a “second amplification transistor” in another context. Similarly, a “first resistor” or a “first switch” in one claim may be recited as a “second resistor” or a “third switch,” respectively, in a different claim (e.g., in separate claim sets). An analogous interpretation applies to differential-related terms such as a “plus transistor” and a “minus transistor.”

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for voltage-to-current conversion have been described in language specific to certain features and/or methods, the subject of the appended claims is not necessarily limited to the specific features or methods described. Rather, the specific features and methods are disclosed as example implementations for voltage-to-current conversion.

What is claimed is:

1. An apparatus comprising:
a voltage-to-current converter comprising:
a plus input transistor;
a minus input transistor;
a plus current-source transistor coupled between the plus input transistor and a power distribution node;
a minus current-source transistor coupled between the minus input transistor and the power distribution node;
a plus resistor coupled between the plus input transistor and the plus current-source transistor; and
a minus resistor coupled between the minus input transistor and the minus current-source transistor.

2. The apparatus of claim 1, wherein the voltage-to-current converter comprises:
a plus switch coupled in parallel with the plus resistor.

3. The apparatus of claim 2, wherein:
the plus switch is configured to at least one of short or bypass the plus resistor responsive to being in a closed state.

4. The apparatus of claim 1, wherein:
the plus resistor comprises a plus adjustable resistor; and
the minus resistor comprises a minus adjustable resistor.

5. The apparatus of claim 4, wherein the voltage-to-current converter comprises:
a plus switch coupled in parallel with the plus adjustable resistor; and
a minus switch coupled in parallel with the minus adjustable resistor.

6. The apparatus of claim 1, wherein the voltage-to-current converter comprises:
a conductive path coupled between the plus resistor and the minus resistor.

7. The apparatus of claim 6, wherein the voltage-to-current converter comprises:
a resistor coupled between the plus resistor and the minus resistor along the conductive path.

8. The apparatus of claim 7, wherein:
the plus resistor, the resistor, and the minus resistor are coupled together in series between the plus input transistor and the minus input transistor.

9. The apparatus of claim 7, wherein:
the resistor is coupled between the plus current-source transistor and the minus current-source transistor.

10. The apparatus of claim 7, wherein the voltage-to-current converter comprises:
a switch coupled in parallel with the resistor.

11. The apparatus of claim 10, wherein the voltage-to-current converter comprises:
a plus switch coupled in parallel with the plus resistor; and
a minus switch coupled in parallel with the minus resistor.

12. The apparatus of claim 7, wherein:
the plus resistor comprises a plus adjustable resistor;
the minus resistor comprises a minus adjustable resistor; and
the resistor comprises an adjustable resistor.

13. The apparatus of claim 12, wherein the voltage-to-current converter comprises:
a plus switch coupled in parallel with the plus adjustable resistor;
a minus switch coupled in parallel with the minus adjustable resistor; and
a switch coupled in parallel with the adjustable resistor.

14. The apparatus of claim 1, wherein the voltage-to-current converter comprises:
a resistor coupled between the plus current-source transistor and the minus current-source transistor.

15. The apparatus of claim 14, wherein:
the resistor is coupled between a channel terminal of the plus current-source transistor and a channel terminal of the minus current-source transistor.

16. The apparatus of claim 15, wherein:
the plus resistor is coupled between a channel terminal of the plus input transistor and the channel terminal of the plus current-source transistor; and
the minus resistor is coupled between a channel terminal of the minus input transistor and the channel terminal of the minus current-source transistor.

17. The apparatus of claim 16, wherein:
the channel terminal of the plus current-source transistor comprises a drain terminal of the plus current-source transistor;
the channel terminal of the minus current-source transistor comprises a drain terminal of the minus current-source transistor;
the channel terminal of the plus input transistor comprises a source terminal of the plus input transistor; and
the channel terminal of the minus input transistor comprises a source terminal of the minus input transistor.

18. The apparatus of claim 1, wherein:
the plus input transistor, the plus resistor, and the plus current-source transistor are coupled together in series between the power distribution node and another power distribution node.

19. The apparatus of claim 18, wherein:
the power distribution node comprises a ground; and
the other power distribution node comprises a voltage supply rail.

20. The apparatus of claim 1, wherein:
the plus input transistor is configured to convert a voltage-mode signal received at a control terminal of the plus input transistor to produce a current-mode signal at a channel terminal of the plus input transistor.

21. The apparatus of claim 1, wherein:
the plus current-source transistor is configured to be biased in a triode region of transistor operation.

22. The apparatus of claim 21, further comprising:
a controller coupled to the voltage-to-current converter, the controller configured to bias the plus current-source transistor in the triode region of transistor operation to reduce nonlinearity of an output signal of the voltage-to-current converter.

23. The apparatus of claim 1, wherein:
the plus current-source transistor is configured to operate as a current source with respect to at least the plus input transistor.

24. The apparatus of claim 23, wherein the plus current-source transistor is configured to:
produce an output current; and
adjust the output current dynamically responsive to voltage swings created by the plus input transistor.

25. The apparatus of claim 24, wherein the plus current-source transistor is configured to:
adjust the output current dynamically to counteract clipping experienced by the plus input transistor.

26. The apparatus of claim 1, further comprising:
a digital-to-analog converter;
a base-band filter coupled between the digital-to-analog converter and the voltage-to-current converter; and
a mixer,
wherein the voltage-to-current converter is coupled between the base-band filter and the mixer.

27. An apparatus comprising:
a voltage-to-current converter comprising:
a plus input transistor;
a minus input transistor;
a plus current-source transistor coupled between the plus input transistor and a power distribution node;
a minus current-source transistor coupled between the minus input transistor and the power distribution node;
means for reducing, in an output signal of the voltage-to-current converter, noise generated by the plus current-source transistor; and
means for reducing, in the output signal of the voltage-to-current converter, noise generated by the minus current-source transistor.

28. A method for voltage-to-current conversion, the method comprising:
receiving a voltage-mode input signal at an input transistor;
producing, using the input transistor, a current-mode output signal;
providing, using a current-source transistor, a current to the input transistor; and
splitting noise generated by the current-source transistor between at least a first path including the input transistor and a resistor and a second path including another resistor.

29. The method of claim 28, further comprising:
biasing the current-source transistor in a triode region of transistor operation during at least part of the providing of the current to the input transistor.

30. An apparatus comprising:
a voltage-to-current converter comprising:
a plus input transistor;
a minus input transistor;
a plus current-source transistor coupled between the plus input transistor and a power distribution node, the plus current-source transistor configured to be biased in a triode region of transistor operation during a voltage-to-current conversion procedure;
a minus current-source transistor coupled between the minus input transistor and the power distribution node, the minus current-source transistor configured to be biased in the triode region of transistor operation during the voltage-to-current conversion procedure; and
a conductive path coupled between the plus input transistor and the minus input transistor and between the plus current-source transistor and the minus current-source transistor.
